(19) United States
(12) Patent Application Publication
(10) Pub. No.: US 2024/0206237 A1
(43) Pub. Date: Jun. 20, 2024

(54) DISPLAY DEVICE

(71) Applicant: LG Display Co., Ltd., Seoul (KR)

(72) Inventors: EunYoung Park, Paju-si (KR); SeungHee Nam, Paju-si (KR); YunHo Kook, Goyang-si (KR); Jonghan Park, Seoul (KR); Chaewoon Lee, Seoul (KR)

(73) Assignee: LG Display Co., Ltd., Seoul (KR)

(21) Appl. No.: 18/389,061

(22) Filed: Nov. 13, 2023

(30) Foreign Application Priority Data
Dec. 14, 2022 (KR) 10-2022-0174695

(51) Int. Cl. H10K 59/122; G09G 3/3233; H10K 59/80

(52) U.S. Cl. CPC H10K 59/122; G09G 3/3233; H10K 59/80515; H10K 59/80518; H10K 59/878; G09G 2300/0842

(57) ABSTRACT

A display device may include: a substrate including a plurality of sub-pixels, including a first sub-pixel; an insulating layer disposed over the substrate and having a first open area in the first sub-pixel, the insulating layer having a side portion facing the first open area in the first sub-pixel; an anode electrode including a first portion disposed in the first open area and a second portion disposed on the side portion of the insulating layer; an organic layer on the anode electrode; and a cathode electrode on the organic layer. The first open area of the insulating layer may have an uneven outer edge in a plan view.

### CROSS-REFERENCE TO RELATED APPLICATION

This application claims the benefit of and priority to Korean Patent Application No. 10-2022-0174695, filed on Dec. 14, 2022, in the Republic of Korea, the entire contents of which are hereby expressly incorporated by reference into the present application.

### BACKGROUND

### Technical Field

The present disclosure relates to a display device.

### Discussion of the Related Art

Recently, as our society advances toward an information-oriented society, the field of display devices for visually expressing an electrical information signal has rapidly advanced. Various display devices having excellent performance in terms of thinness, lightness, and low power consumption are being developed correspondingly.

Representative display devices include a liquid crystal display device (LCD), an electro-wetting display device (EWD), and an organic light emitting display device (OLED).

An electroluminescent display device represented by the organic light emitting display device is a self-luminous display device and can be manufactured to be light and thin since it does not require a separate light source, unlike the liquid crystal display device having a separate light source. In addition, the electroluminescent display device has advantages in terms of power consumption due to a low voltage driving, and is excellent in terms of a color implementation, a response speed, a viewing angle, and a contrast ratio (CR). Therefore, electroluminescent display devices have been expected to be used in various fields of application.

In the electroluminescent display device, a plurality of organic layers including a light emitting layer between two electrodes, that is, an anode electrode and a cathode electrode, are disposed, to form a light emitting element. For example, when holes from the anode electrode are injected into the light emitting layer and electrons from the cathode electrode are injected into the light emitting layer, the injected electrons and holes recombine with each other in the light emitting layer to form excitons and emit light.

On the other hand, the electroluminescent display device has a limitation in that light extraction efficiency of the electroluminescent display device may be lowered, causing a decrease in luminous efficiency, since a portion of light emitted from the light emitting layer may not come out of a display panel and may be trapped inside the display panel.

### SUMMARY

The present disclosure is directed to a display device that substantially obviates one or more of the problems due to limitations and disadvantages of the related art.

An object to be achieved by the present disclosure is to provide a display device having improved light extraction efficiency and an improved luminance viewing angle.

Another object to be achieved by the present disclosure is to provide a display device in which Rainbow Mura is reduced.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, a display device may include: a substrate including a plurality of sub-pixels, including a first sub-pixel; an insulating layer disposed over the substrate and having a first open area in the first sub-pixel, the insulating layer having a side portion facing the first open area in the first sub-pixel; an anode electrode including a first portion disposed in the first open area and a second portion disposed on the side portion of the insulating layer; an organic layer on the anode electrode; and a cathode electrode on the organic layer, wherein the first open area of the insulating layer may have an uneven outer edge in a plan view.

In another aspect of the present disclosure, a display device may include: a substrate including a plurality of sub-pixels configured to emit light, the plurality of sub-pixels including a first sub-pixel; an insulating layer over the substrate; an anode electrode on the insulating layer; an organic layer on the anode electrode; and a cathode electrode on the organic layer, wherein the anode electrode, the organic layer, and the cathode electrode in the first sub-pixel in combination are configured to emit light, and wherein the first sub-pixel includes an emission area with an uneven outer edge in a plan view.

Other detailed matters of example embodiments are included in the detailed description and the drawings.

According to the present disclosure, an anode electrode may have a side mirror structure, so that a display device having excellent luminous efficiency can be provided.

According to the present disclosure, an area of a side mirror may be increased by patterning a side portion of the planarization layer and an edge of an open area, so that luminous efficiency and a luminance viewing angle can be improved.

According to the present disclosure, Rainbow Mura in a concentric form can be prevented through irregular reflection by reducing periodicity of patterns at an edge of an open area and a side portion of a planarization layer.

The effects according to the present disclosure are not limited to the effects and advantages discussed above by way of example, and various additional effects and advantages may be obtained with the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF THE DRAWINGS

The accompanying drawings, which are included to provide a further understanding of the disclosure and are incorporated in and constitute a part of this application, illustrate example embodiments of the disclosure and together with the description serve to explain the principles of the disclosure.

FIG. 1 is a configuration diagram illustrating an example display device according to the present disclosure.

FIG. 2 is a plan view schematically illustrating a display device according to example embodiments of the present disclosure.

FIG. 3 is an equivalent circuit diagram of a sub-pixel of the display device according to example embodiments of the present disclosure.

FIG. 4 is a view illustrating a sub-pixel structure of a first example embodiment of the present disclosure.

FIG. 5 is a view illustrating a cross-sectional structure of a display panel according to the first example embodiment of the present disclosure.

FIG. 6A is a perspective view illustrating by way of example a first open area of a third planarization layer in a sub-pixel structure of FIG. 5.

FIG. 6B is a perspective view illustrating by way of example a second open area of a bank in the sub-pixel structure of FIG. 5.

FIGS. 7A and 7B are views showing light emission images of Comparative Examples.

FIG. 8 is a view showing by way of example a light emission image according to the first example embodiment of the present disclosure.

FIG. 9 is a view illustrating a sub-pixel structure of a second example embodiment of the present disclosure.

FIG. 10 is a view illustrating by way of example a light emission image of the second example embodiment of the present disclosure.

FIGS. 11A to 11C are example views showing unevenness images.

FIGS. 12A to 12C are example graphs showing luminous efficiency according to pixels per inch (PPI).

FIG. 13 is a view illustrating a sub-pixel structure of a third example embodiment of the present disclosure.

FIG. 14 is a view illustrating by way of example a light emission image of the third example embodiment of the present disclosure.

FIG. 15 is a view illustrating a sub-pixel structure of a fourth example embodiment of the present disclosure.

FIG. 16 is a view illustrating by way of example a light emission image of the fourth example embodiment of the present disclosure.

FIG. 17 is a view illustrating a sub-pixel structure of a fifth example embodiment of the present disclosure.

FIG. 18 is a view illustrating by way of example a light emission image of the fifth example embodiment of the present disclosure.

FIG. 19 is a view illustrating a sub-pixel structure of a sixth example embodiment of the present disclosure.

FIG. 20 is a view illustrating a sub-pixel structure of a seventh example embodiment of the present disclosure.

### DETAILED DESCRIPTION

Reference will now be made in detail to embodiments of the present disclosure, examples of which are illustrated in the accompanying drawings.

Advantages and features of the present disclosure, and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete, and will fully convey the scope of the present disclosure to those skilled in the art.

The shapes, dimensions, areas, lengths, thicknesses, ratios, angles, numbers, and the like, which are illustrated in the drawings to describe various example embodiments of the present disclosure, are merely given by way of example. Therefore, the present disclosure is not limited to such illustrated details in the drawings. Like reference numerals generally denote like elements throughout the specification, unless otherwise specified.

In the following description, where a detailed description of a relevant known function or configuration may unnecessarily obscure aspects of the present disclosure, a detailed description of such a known known function or configuration may be omitted or be briefly discussed.

Where a term like “comprise,” “have,” “include,” “contain,” “constitute,” “made up of,” or “formed of” is used, one or more other elements may be added unless a more limiting term, such as “only” or the like, is used. An element described in the singular form is intended to include a plurality of elements, and vice versa, unless the context clearly indicates otherwise.

In construing an element, the element should be construed as including an error or tolerance range even where no explicit description of such an error or tolerance range is provided.

Where a positional relationship between two elements is described, for example, as “on,” “above,” “below,” “beneath,” and “next,” or the like, one or more other elements may be located between the two elements unless a more limiting term, such as “direct(ly),” is used.

For example, where a first element is described as being positioned “on” a second element, the first element may be positioned above and contact the second element or may merely be above the second element with one or more additional elements disposed between the first and second elements.

Although the terms “first,” “second,” and the like may be used herein to describe various elements, these elements should not be interpreted to be limited by these terms as they are not used to define a particular essence, order, sequence, precedence, or number of such elements. These terms are used only to distinguish one element from another. For example, a first element could be termed a second element, and a second element could similarly be termed a first element, without departing from the scope of the present disclosure.

A size and a thickness of each component illustrated in the drawing are illustrated for convenience of description, and the present disclosure is not limited to the specific size or thickness of the component illustrated.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other, or may be carried out together in association with each other.

Hereinafter, various detailed example embodiments of the present disclosure will be described with reference to the accompanying drawings.

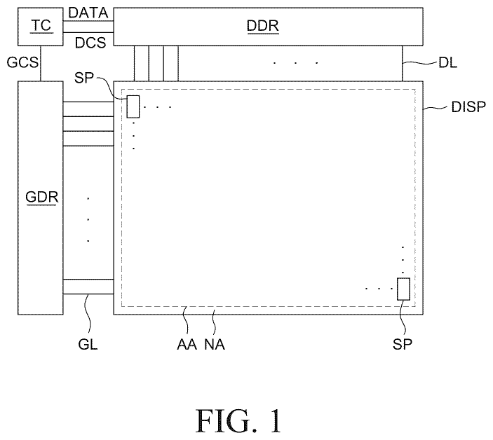

FIG. 1 is a configuration diagram showing an example display device according to the present disclosure.

Display devices according to example embodiments of the present disclosure may include a display device, an illumination device, an electroluminescent display device, and the like. Hereinafter, for convenience of description, the display device will be mainly described. However, the following descriptions may equally be applied to various other display devices, such as an illumination device and an electroluminescent display device.

As illustrated in FIG. 1, the display devices according to example embodiments of the present disclosure may include a display panel DISP for displaying an image or outputting light and a driving circuit for driving the display panel DISP.

In the display panel DISP, a plurality of data lines DL and a plurality of gate lines GL may be disposed, and a plurality of sub-pixels SP defined by the plurality of data lines DL and the plurality of gate lines GL may be arranged in a matrix form.

The plurality of data lines DL and the plurality of gate lines GL of the display panel DISP may be disposed to cross each other. For example, the plurality of gate lines GL may be arranged in units of rows or columns, and the plurality of data lines DL may be arranged in units of columns or rows. Hereinafter, for convenience of explanation, it is assumed that the plurality of gate lines GL are arranged in rows and the plurality of data lines DL are arranged in columns.

In addition to the plurality of data lines DL and the plurality of gate lines GL, other types of signal lines may be disposed on the display panel DISP according to sub-pixel structures employed. For example, a driving voltage line, a reference voltage line, or a common voltage line may be further disposed thereon.

Examples of the display panel DISP may include various types of panels, such as a liquid crystal display (LCD) panel and an organic light emitting diode (OLED) panel.

Types of signal lines disposed on the display panel DISP may vary depending on the sub-pixel structures and panel types. Also, in the present disclosure, the signal line may conceptually include an electrode to which a signal is applied.

The display panel DISP may include an active area AA, in which an image is displayed, and a non-active area NA outside the active area AA, in which an image is not displayed. Here, the non-active area NA may also be referred to as a bezel area.

A plurality of sub-pixels SP for displaying an image may be disposed in the active area AA.

A pad unit for electrical connection with a data driver DDR may be disposed in the non-active area NA, and a plurality of data link lines for connection between the pad unit and the plurality of data lines DL may be disposed. Here, the plurality of data link lines may be portions of the plurality of data lines DL that extend to the non-active area NA, or may be separate patterns that are electrically connected to the plurality of data lines DL.

In addition, lines related to gate driving may be disposed in the non-active area NA to transfer a voltage that is required for gate driving to a gate driver GDR through the pad unit to which the data driver DDR is electrically connected. For example, the lines related to gate driving may include clock lines for transmitting clock signals, gate voltage lines for transmitting gate voltages VGH and VGL, gate driving control signal lines for transmitting various control signals that are necessary for generating scan signals, and the like. Unlike the gate lines GL disposed in the active area AA, these lines related to gate driving may be disposed in the non-active area NA.

The driving circuit may include, for example, the data driver DDR for driving the plurality of data lines DL, the gate driver GDR for driving the plurality of gate lines GL, and a timing controller TC for controlling the data driver DDR and the gate driver GDR.

As described above, the data driver DDR may drive the plurality of data lines DL by outputting data voltages to the plurality of data lines DL.

Also, the gate driver GDR may drive the plurality of gate lines GL by outputting scan signals to the plurality of gate lines GL.

For example, the timing controller TC may control driving operations of the data driver DDR and the gate driver GDR by supplying various control signals, such as data control signals DCS and gate control signals GCS, that are necessary for the driving operations of the data driver DDR and gate driver GDR. Also, the timing controller TC may supply image data DATA to the data driver DDR.

The timing controller TC may start scanning according to a timing implemented in each frame, may convert input image data that is input from an external source in accordance with a data signal format that is used in the data driver DDR and output converted image data DATA, and may control data driving at an appropriate time in accordance with the scanning.

For example, in order to control the data driver DDR and gate driver GDR, the timing controller TC may receive various timing signals, such as a vertical synchronization signal Vsync, a horizontal synchronization signal Hsync, an input data enable (DE) signal, a clock signal CLK, and the like, from an external source to generate various control signals, and may output the control signals to the data driver DDR and the gate driver GDR.

For example, to control the gate driver GDR, the timing controller TC may output various gate control signals GCS, including a gate start pulse GSP, a gate shift clock GSC, a gate output enable signal GOE, and the like.

In addition, to control the data driver DDR, the timing controller TC may output various data control signals DCS, including a source start pulse SSP, a source sampling clock SSC, a source output enable signal SOE, and the like.

The timing controller TC may be implemented as a separate component from the data driver DDR, or may be integrated with the data driver DDR and implemented as an integrated circuit.

The data driver DDR may receive the image data DATA from the timing controller TC and may supply data voltages to the plurality of data lines DL to drive the plurality of data lines DL. The data driver DDR may also be called a source driver.

The data driver DDR may receive and transmit various signals from and to the timing controller TC through various interfaces.

In addition, the gate driver GDR may sequentially drive the plurality of gate lines GL by sequentially supplying scan signals to the plurality of gate lines GL. Here, the gate driver GDR may also be referred to as a scan driver.

The gate driver GDR may sequentially supply scan signals of an on-voltage or an off-voltage to the plurality of gate lines GL under the control of the timing controller TC.

The data driver DDR may convert the image data DATA received from the timing controller TC into data voltages in an analog format when a specific gate line is opened by the gate driver GDR, and may supply the data voltages to the plurality of data lines DL.

The data driver DDR may be located at only one side of the display panel DISP, or in some cases, may be located at both sides of the display panel DISP according to a driving method or a panel design method. For example, the data driver DDR may be located at an upper side or a lower side of the display panel DISP, or may be located at both the upper side and the lower side of the display panel DISP.

The gate driver GDR may be located at only one side of the display panel DISP, or in some cases, may be located oatn both sides of the display panel DISP according to a driving method, a panel design method, and the like. For example, the gate driver GDR may be located at a left side or right side of the display panel DISP, or may be located at both the left and right sides.

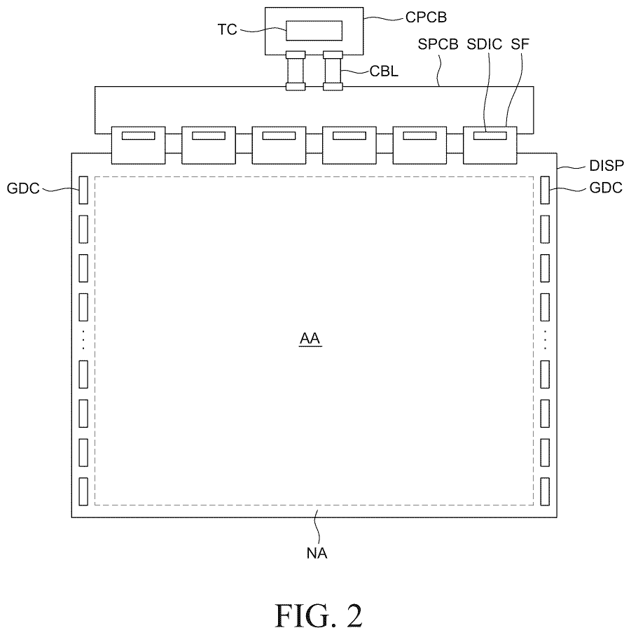

The data driver DDR may be implemented by including one or more source driver integrated circuits SDIC (see FIG. 2).

For example, each of the source driver integrated circuits SDIC may include a shift register, a latch circuit, a digital-to-analog converter (DAC), an output buffer, and the like. In some cases, the data driver DDR may further include one or more analog-to-digital converters (ADC).

In addition, each source driver integrated circuit SDIC may be connected to a bonding pad of the display panel DISP or directly disposed on the display panel DISP in a tape automated bonding (TAB) type or a chip on glass (COG) type. In some cases, each source driver integrated circuit SDIC may be disposed to be integrated with the display panel DISP. In addition, each source driver integrated circuit SDIC may be implemented as a chip on film (COF) type. In this case, each source driver integrated circuit SDIC may be mounted on a circuit film and be electrically connected to the data line DL of the display panel DISP through the circuit film.

The gate driver GDR may include a plurality of gate driving circuits GDC (see FIG. 2). Here, the plurality of gate driving circuits GDC may correspond to the plurality of gate lines GL, respectively.

For example, each gate driving circuit GDC may include a shift register and a level shifter.

The gate driving circuit GDC may be connected to the bonding pad of the display panel DISP in a tape automated bonding (TAB) type or a chip on glass (COG) type. Also, each gate driving circuit GDC may be implemented as a chip on film (COF) type. In this case, each gate driving circuit GDC may be mounted on a circuit film and be electrically connected to the gate line GL of the display panel DISP through the circuit film. In addition, each gate driving circuit GDC may be implemented as a gate-in-panel (GIP) type and be embedded in the display panel DISP. For example, each gate driving circuit GDC may be formed directly on the display panel DISP.

FIG. 2 is a plan view schematically illustrating a display device according to example embodiments of the present disclosure.

As illustrated in FIG. 2, in the display devices according to example embodiments of the present disclosure, the data driver may be implemented as the chip on film (COF) type among the various types TAB, COG, COF and the like described above, and the gate driver may be implemented as the gate-in-panel (GIP) type among the various types TAB, COG, COF, GIP, and the like. However, the present disclosure is not limited thereto and may be implemented in various other types.

The data driver DDR may be implemented with the one or more source driver integrated circuits SDIC. FIG. 2 illustrates a case in which the data driver DDR is implemented with a plurality of source driver integrated circuits SDIC, but the present disclosure is not limited thereto.

Where the data driver is implemented as the COF type, the respective source driver integrated circuits SDIC implementing the data driver DDR may be mounted on source-side circuit films SF.

For example, one side of the source-side circuit films SF may be electrically connected to the pad unit (an assembly of pads) disposed in the non-active area NA of the display panel DISP.

In addition, lines for electrically connecting the source driver integrated circuits SDIC and the display panel DISP may be disposed on the source-side circuit films SF.

The display device may include one or more source printed circuit boards SPCB for circuit connection between the plurality of source driver integrated circuits SDIC and other devices, and a control printed circuit board CPCB for mounting control components and various electrical devices.

For example, the other sides of the source-side circuit films SF on which the source driver integrated circuits SDIC are mounted may be connected to the one or more source printed circuit boards SPCB. For example, the source-side circuit films SF on which the source driver integrated circuits SDIC are mounted may have one side thereof that is electrically connected to the non-active area NA of the display panel DISP and the other side thereof that is electrically connected to the source printed circuit board SPCB.

In addition, the timing controller TC for controlling operations of the data driver DDR and the gate driver GDR may be disposed on the control printed circuit board CPCB.

In the control printed circuit board CPCB, a power management integrated circuit (PMIC) that supplies various voltages or currents to the display panel DISP, the data driver, the gate driver, and the like, or controls various voltages or currents to be supplied may be further disposed.

The source printed circuit board SPCB and the control printed circuit board CPCB may be connected in circuit through at least one connection member CBL.

For example, the connection member CBL may be a flexible printed circuit FPC, a flexible flat cable FFC, or the like.

For example, the one or more source printed circuit boards SPCB and the control printed circuit board CPCB may be integrated into one printed circuit board.

Where the gate driver GDR is implemented as the gate-in-panel (GIP) type, a plurality of gate driving circuits GDC included in the gate driver GDR may be directly formed on the non-active area NA of the display panel DISP.

Each of the gate driving circuits GDC may output a corresponding scan signal to a corresponding gate line GL disposed in the active area AA of the display panel DISP.

The plurality of gate driving circuits GDC disposed on the display panel DISP may be supplied with various signals, such as clock signals, a high level gate voltage VGH, a low level gate voltage VGL, a start signal VST, a reset signal RST and the like, that are necessary for generating scan signals, through the lines related to gate driving disposed in the non-active area NA.

The lines related to gate driving disposed in the non-active area NA may be electrically connected to the source-side circuit film SF disposed closest to the plurality of gate driving circuits GDC.

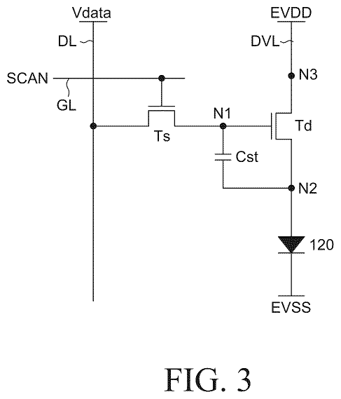

FIG. 3 is an equivalent circuit diagram of a sub-pixel of the display device according to example embodiments of the present disclosure.

FIG. 3 is an equivalent circuit diagram for one sub-pixel where the display panel according to example embodiments of the present disclosure is an electroluminescent display panel.

As illustrated in FIG. 3, each sub-pixel may be implemented to include a light emitting element 120, a driving transistor Td for driving the light emitting element 120, a switching transistor Ts electrically connected between a first node N1 of the driving transistor Td and a corresponding data line DL, a storage capacitor Cst electrically connected between the first node N1 and a second node N2 of the driving transistor Td, and the like.

The light emitting element 120 may include an anode electrode, a plurality of organic layers, and a cathode electrode.

According to an illustration of FIG. 3, the anode electrode (also referred to as a pixel electrode) of the light emitting element 120 may be electrically connected to the second node N2 of the driving transistor Td. In this case, a base voltage EVSS may be applied to the cathode electrode (also referred to as a common electrode) of the light emitting element 120.

The base voltage EVSS may be a ground voltage or a voltage higher or lower than the ground voltage. Also, the base voltage EVSS may vary according to driving conditions. For example, the base voltage EVSS during image driving and the base voltage EVSS during sensing driving may be set differently.

The driving transistor Td may drive the light emitting element 120 by supplying a driving current to the light emitting element 120.

The driving transistor Td may include the first node N1, the second node N2, and a third node N3.

The first node N1 of the driving transistor Td may be a gate node and may be electrically connected to a source node or a drain node of the switching transistor Ts. The second node N2 of the driving transistor Td may be one of a source node and a drain node, and may be electrically connected to the anode electrode (or cathode electrode) of the light emitting element 120. The third node N3 of the driving transistor Td may be the other of the drain node and the source node, may receive a driving voltage EVDD applied thereto, and may be electrically connected to a driving voltage line DVL supplying the driving voltage EVDD.

The storage capacitor Cst may be electrically connected between the first node N1 and the second node N2 of the driving transistor Td and may maintain a data voltage Vdata corresponding to an image signal voltage or a voltage corresponding thereto for one frame period (or a set time).

One of the drain node and the source node of the switching transistor Ts may be electrically connected to the corresponding data line DL, and the other of the drain node and the source node of the switching transistor Ts may be electrically connected to the first node N1 of the driving transistor Td. Also, a gate node of the switching transistor Ts may be electrically connected to a corresponding gate line GL and receive a scan signal SCAN applied thereto.

The gate node of the switching transistor Ts may receive the scan signal SCAN through the corresponding gate line GL so that turning on and off of the switching transistor Ts can be controlled.

The switching transistor Ts may be turned on by the scan signal SCAN and may transfer the data voltage Vdata supplied from the corresponding data line DL to the first node N1 of the driving transistor Td.

Meanwhile, the storage capacitor Cst is not a parasitic capacitor, which is an internal capacitor existing between the first node N1 and the second node N2 of the driving transistor Td, but may be an external capacitor that is intentionally designed external to the driving transistor Td.

For example, each of the driving transistor Td and the switching transistor Ts may be an n-type transistor or a p-type transistor.

Each sub-pixel structure is illustrated in FIG. 3 as a 2T(Transistor)1C (Capacitor) structure, which is only an example for descriptions, but may further include one or more additional transistors and/or, in some cases, one or more additional capacitors. Alternatively, each of the plurality of sub-pixels may have the same structure, or some of the plurality of sub-pixels may have different structures.

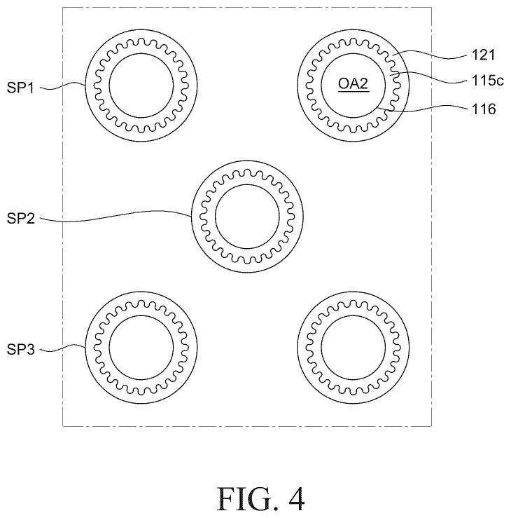

FIG. 4 is a view illustrating a sub-pixel structure of a first example embodiment of the present disclosure.

FIG. 4 shows an example of a portion of a display panel on which five sub-pixels, including SP1, SP2, and SP3, are disposed, and shows a bank 116 including a second open area OA2 which is an emission area, an anode electrode 121, and a third planarization layer 115c as an example.

As illustrated in FIG. 4, the display panel according to the first exemplary embodiment of the present disclosure may include a pixel area in which a plurality of sub-pixels SP1, SP2, and SP3 are present and a line area in which various signal lines are disposed.

The plurality of first sub-pixels SP1, second sub-pixels SP2, and third sub-pixels SP3 may be disposed in the pixel area.

For example, the first sub-pixel SP1 may be a red sub-pixel.

For example, the second sub-pixel SP2 may be a green sub-pixel.

For example, the third sub-pixel SP3 may be a blue sub-pixel.

For example, the first sub-pixel SP1, the second sub-pixel SP2, and the third sub-pixel SP3 may have circular shapes or polygonal shapes, but the present disclosure is not limited thereto. Here, the shapes of the sub-pixels SP1, SP2, and SP3 may be defined by shapes of the anode electrodes 121, but the present disclosure is not limited thereto.

FIG. 4 illustrates an example in which one first sub-pixel SP1, one second sub-pixel SP2, and one third sub-pixel SP3 are gathered to form one pixel, but the present disclosure is not limited thereto.

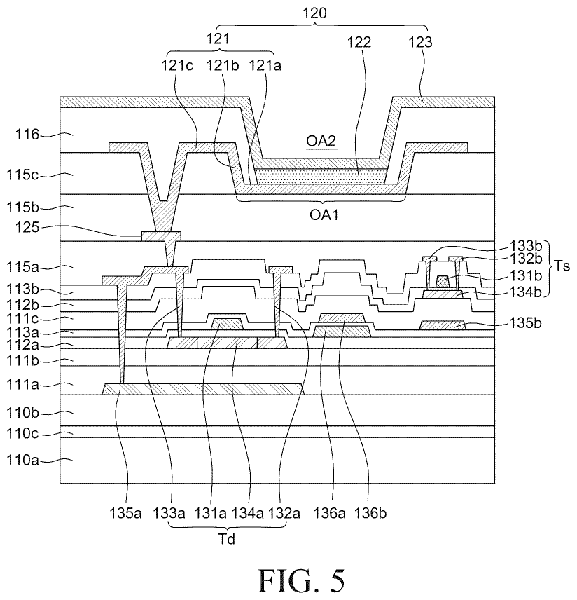

In another aspect, in the present disclosure, in addition to a main emission area, a reflective emission area may be added due to a side mirror (SM) structure of the anode electrode 121, so that each emission area can be expanded compared to each of the sub-pixels SP1, SP2, and SP3. A detailed description related to the side mirror structure will be described later with reference to FIGS. 5 to 7.

In addition, in the first example embodiment of the present disclosure, a side portion of the third planarization layer 115c in contact with a side surface of the anode electrode 121 having the side mirror structure may have an uneven shape, such as an iris flower pattern, a zigzag pattern, or wavy pattern, when viewed in a planar perspective. Accordingly, an area of a side mirror of the anode electrode 121 can be substantially increased. Thus, luminous efficiency can be improved, a luminance viewing angle can be improved, and Rainbow Mura in a concentric form can be reduced through irregular reflection.

FIG. 5 is a view illustrating a cross-sectional structure of a display panel according to the first example embodiment of the present disclosure.

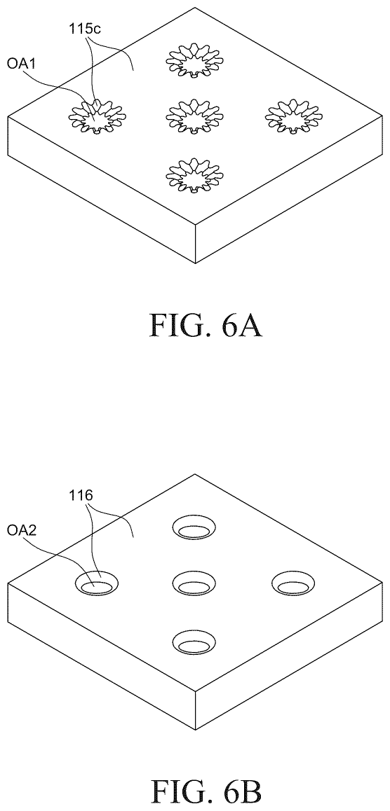

FIG. 6A is a perspective view exemplarily illustrating a first open area of a third planarization layer in the example sub-pixel structure of FIG. 5.

FIG. 6B is a perspective view exemplarily illustrating a second open area of a bank in the example sub-pixel structure of FIG. 5.

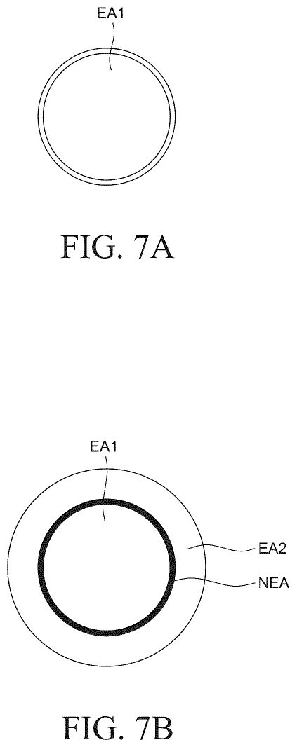

FIGS. 7A and 7B are views showing light emission images of Comparative Examples.

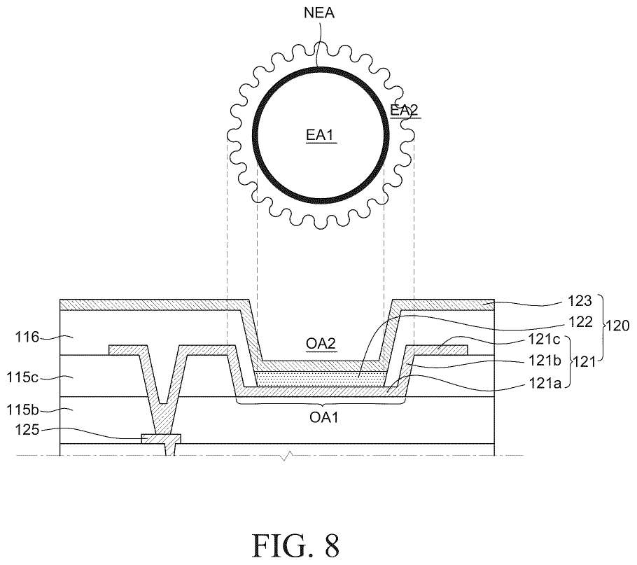

FIG. 8 is a view showing by way of example a light emission image according to the first example embodiment of the present disclosure.

FIG. 5 shows a portion of a cross-section of one sub-pixel of the display panel according to the first example embodiment of the present disclosure.

In FIG. 5, an illustration of components above the light emitting element 120 is omitted for convenience, but the present disclosure is not limited thereto. The present disclosure may include an encapsulation layer and a touch sensor layer over the light emitting element 120.

FIGS. 6A and 6B show by way of example a first open area OA1 of the third planarization layer 115c in a concave portion of the third planarization layer 115c and the second open area OA2 of the bank 116 included in the display panel according to the first example embodiment of the present disclosure.

FIG. 7A shows by way of example a light emission image of Comparative Example in which the SM structure of the present disclosure is not applied, and FIG. 7B shows by way of example a light emission image of Comparative Example in which the SM structure is applied but the side portion of the third planarization layer has a circular shape.

FIG. 8 shows by way of example a portion of a cross-sectional structure of the example sub-pixel shown in FIG. 5 and a light emission image corresponding thereto.

As illustrated in FIG. 5, FIGS. 6A and 6B, and FIG. 8, the driving transistor Td, the switching transistor Ts, and the light emitting element 120 may be disposed above substrates 110a, 110b, and 110c.

For example, the substrates 110a, 110b, and 110c may include a first substrate 110a, a second substrate 110b, and an interlayer substrate insulating layer 110c. The interlayer substrate insulating layer 110c may be disposed between the first substrate 110a and the second substrate 110b.

As described above, by configuring the substrates 110a, 110b, and 110c with the first substrate 110a, the second substrate 110b, and the interlayer substrate insulating layer 110c, moisture permeation can be prevented or reduced. For example, the first substrate 110a and the second substrate 110b may be polyimide (PI) substrates.

Transistors, such as the driving transistor Td and the switching transistor Ts, may be disposed above the substrates 110a, 110b, and 110c.

A multi-buffer layer 111a may be disposed on the second substrate 110b, and an active buffer layer 111b may be disposed on the multi-buffer layer 111a.

A first light blocking layer 135a may be disposed on the second substrate 110b. However, the present disclosure is not limited thereto, and the first light blocking layer 135a may be disposed on the multi-buffer layer 111a.

The first light blocking layer 135a may serve as a light shielding element.

The multi-buffer layer 111a may be disposed on the first light blocking layer 135a.

The active buffer layer 111b may be disposed on the multi-buffer layer 111a.

The first active layer 134a of the driving transistor Td may be disposed on the active buffer layer 111b.

A first gate insulating layer 112a may be disposed on the first active layer 134a.

Also, a first gate electrode 131a of the driving transistor Td may be disposed on the first gate insulating layer 112a.

Also, for example, a gate material layer 136a may be disposed on the first gate insulating layer 112a at a location different from a location at which the driving transistor Td is formed. For example, the gate material layer 136a may be a first storage electrode but is not limited thereto.

A first interlayer insulating layer 113a may be disposed on the first gate electrode 131a.

A metal layer 136b may be disposed on the first interlayer insulating layer 113a. For example, the metal layer 136b may be a second storage electrode but is not limited thereto.

In this case, the metal layer 136b may constitute a storage capacitor together with the gate material layer 136a but is not limited thereto.

Also, for example, a second light blocking layer 135b may be disposed on the first interlayer insulating layer 113a at a location different from a location at which the metal layer 136b is formed.

A buffer layer 111c may be disposed on the metal layer 136b and the second light blocking layer 135b.

A second active layer 134b of the switching transistor Ts may be disposed on the buffer layer 111c.

A second gate insulating layer 112b may be disposed on the second active layer 134b.

In addition, a second gate electrode 131b of the switching transistor Ts may be disposed on the second gate insulating layer 112b.

A second interlayer insulating layer 113b may be disposed on the second gate electrode 131b.

A first source electrode 132a and a first drain electrode 133a of the driving transistor Td may be disposed on the second interlayer insulating layer 113b. In addition, a second source electrode 132b and a second drain electrode 133b of the switching transistor Ts may be disposed on the second interlayer insulating layer 113b.

For example, the first source electrode 132a and the first drain electrode 133a may be electrically connected to one side and the other side of the first active layer 134a, respectively, through respective contact holes provided in the second interlayer insulating layer 113b, the second gate insulating layer 112b, the buffer layer 111c, the first interlayer insulating layer 113a, and the first gate insulating layer 112a.

Further, for example, a part of the first drain electrode 133a may be electrically connected to one side of the first light blocking layer 135a through contact holes provided in the second interlayer insulating layer 113b, the second gate insulating layer 112b, the buffer layer 111c, the first interlayer insulating layer 113a, the first gate insulating layer 112a, the active buffer layer 111b, and the multi-buffer layer 111a.

In addition, for example, the second source electrode 132b and the second drain electrode 133b may be electrically connected to one side and the other side of the second active layer 134b, respectively, through respective contact holes provided in the second interlayer insulating layer 113b and the second gate insulating layer 112b.

A portion of the first active layer 134a overlapping the first gate electrode 131a may be a channel region. For example, one of the first source electrode 132a and the first drain electrode 133a may be connected to one side of the channel region in the first active layer 134a, and the other of the first source electrode 132a and the first drain electrode 133a may be connected to the other side of the channel region in the first active layer 134a.

Also, a portion of the second active layer 134b overlapping the second gate electrode 131b may be a channel region. For example, one of the second source electrode 132b and the second drain electrode 133b may be connected to one side of the channel region in the second active layer 134b, and the other of the second source electrode 132b and the second drain electrode 133b may be connected to the other side of the channel region in the second active layer 134b.

Although not shown, a passivation layer may be disposed on the first source electrode 132a and the first drain electrode 133a, and on the second source electrode 132b and the second drain electrode 133b.

Planarization layers 115a and 115b may be disposed on the first source electrode 132a and the first drain electrode 133a, and on the second source electrode 132b and the second drain electrode 133b. For example, the planarization layers 115a and 115b may include a first planarization layer 115a and a second planarization layer 115b.

The first planarization layer 115a may be disposed on the passivation layer.

A connection electrode 125 may be disposed on the first planarization layer 115a.

For example, the connection electrode 125 may be electrically connected to one of the first source electrode 132a and the first drain electrode 133a through a contact hole provided in the first planarization layer 115a.

The second planarization layer 115b may be disposed on the connection electrode 125.

The third planarization layer 115c may be disposed on the second planarization layer 115b. In other example embodiments, the second planarization layer 115b and the third planarization layer 115c may be formed as a single layer such that the second planarization layer 115b is part of the third planarization layer 115c.

The third planarization layer 115c may be formed of an organic material, such as an acrylic resin or an epoxy resin, and may be formed of, for example, photo acrylic (PAC). The third planarization layer 115c may also be referred to as a planarization layer or an insulating layer.

For example, the third planarization layer 115c may include a first open area OA1 where portions of the third planarization layer 115c corresponding to a main emission area EA1, a reflective emission area EA2, and a non-emission area NEA of the sub-pixel are removed (open). Here, an entire thickness or less than an entire thickness of the third planarization layer 115c at these portions may be removed to form the first open area OA1.

When viewed in a planar perspective, the first open area OA1 may have an approximately (overall, or generally) circular shape in which an edge thereof may have an uneven shape, such as an iris flower pattern, a zigzag pattern, or a wavy pattern (see, e.g., FIG. 6A), but the present disclosure is not limited thereto. For example, the edge of the first open area OA1 according to example embodiments of the present disclosure may have an uneven shape including a plurality of polygonal patterns.

The third planarization layer 115c may include an upper surface and a side portion.

The upper surface of the third planarization layer 115c is a surface of the third planarization layer 115c located at an uppermost portion and may be substantially parallel to the second substrate 110b.

In addition, the side portion of the third planarization layer 115c may be a surface extending laterally or diagonally from the upper surface of the third planarization layer 115c. For example, the side portion of the third planarization layer 115c may be tapered or inclined at a predetermined angle. For example, the side portion of the third planarization layer 115c may be tapered or inclined at an angle of 30° to 65° with respect to the upper surface of the third planarization layer 115c, but is not limited thereto.

The side portion of the third planarization layer 115c may have an uneven shape, such as an iris flower pattern, a zigzag pattern, or a wavy pattern, in the same manner as the edge of the first open area OA1 when viewed in a planar perspective (see, e.g., FIG. 6A), but the present disclosure is not limited thereto. The side portion of the third planarization layer 115c according to the present disclosure may have an uneven shape including a plurality of polygonal patterns.

For example, the anode electrode 121 may be disposed on the upper surface and the side portion of the third planarization layer 115c and an upper surface of the second planarization layer 115b. For example, the anode electrode 121 may be disposed on the upper surface and the side portion of the third planarization layer 115c and the first open area OA1.

Also, for example, the anode electrode 121 disposed on the first open area OA1 may contact the upper surface of the second planarization layer 115b.

In addition, for example, the anode electrode 121 may include a first area 121a in the first open area OA1 and having a surface that is substantially parallel to a surface of the second substrate 110b and may include a second area 121b extending from the first area 121a and having a predetermined angle with respect to the second substrate 110b. Also, for example, the first area 121a of the anode electrode 121 may correspond to the first open area OA1. For example, the second area 121b of the anode electrode 121 may correspond to the side portion of the third planarization layer 115c. Accordingly, the second area 121b of the anode electrode 121 may be referred to as a side portion of the anode electrode 121.

In example embodiments of the present disclosure, the second area 121b of the anode electrode 121 is a portion having a side mirror shape and may constitute a side mirror (SM) structure. The SM structure of the anode electrode 121 may be formed in the first open area OA1. For example, the SM structure of the anode electrode 121 may form the reflective emission area EA2. For example, the reflective emission area EA2 may follow an outline of the main emission area EA1 and may have an uninterrupted ring shape or a disconnected ring shape. In the case of the disconnected ring shape, it may be a shape which surrounds the outline of the main emission area EA1 but is disconnected in the middle thereof.

According to the first example embodiment of the present disclosure, as the side portion of the third planarization layer 115c has an uneven shape, such as an iris flower pattern, a zigzag pattern, or a wavy pattern, the second area 121b of the anode electrode 121 deposited thereon may also have an uneven shape, such as an iris flower pattern, a zigzag pattern, or a wavy pattern. Accordingly, as an area of a side mirror, that is, the second area 121b of the anode electrode 121 is increased, luminous efficiency can be improved and a luminance viewing angle can be improved.

As described above, the SM structure formed in the first open area OA1 may form the reflective emission area EA2. As a part of light emitted by the light emitting element 120 is reflected from the second area 121b of the anode electrode 121 by the SM structure, the reflective emission area EA2 having a ring shape may be formed. Accordingly, luminous efficiency may be improved.

In addition, for example, an edge of the reflective emission area EA2 may correspond to a shape of the side portion of the third planarization layer 115c and the second area 121b of the anode electrode 121 and, thus, may have an uneven shape, such as an iris flower pattern, a zigzag pattern, or wavy pattern. In the first example embodiment of the present disclosure, since the side portion of the third planarization layer 115c and the second area 121b of the anode electrode 121 are formed to have an uneven shape, such as an iris flower pattern, a zigzag pattern, or a wavy pattern, it is possible to reduce periodicity of the patterns and prevent Rainbow Mura in a concentric form through irregular reflection.

Here, as illustrated in FIG. 7A, only one main emission area EA1 may be present in a Comparative Example to which the SM structure of the present disclosure is not applied. As illustrated in FIG. 7B, the reflective emission area EA2 may be present around the main emission area EA1 due to the SM structure in another Comparative Example to which the SM structure is applied, but the side portion of the third planarization layer has a circular shape. In addition, as shown in FIG. 8, in the case of the first example embodiment in which an example SM structure of the present disclosure is applied and the side portion of the third planarization layer 115c has an uneven shape, such as an iris flower pattern, a zigzag pattern, or a wavy pattern, the reflective emission area EA2 may be present around the main emission area EA1, and an edge of the reflective emission area EA2 may have an uneven shape, such as an iris flower pattern, a zigzag pattern, or a wavy pattern, corresponding to the shape of the side portion of the third planarization layer 115c.

For example, in the case of the first example embodiment of the present disclosure, the main emission area EA1 may have an approximately circular shape, and the non-emission area NEA may have a shape of an approximately circular ring surrounding the main emission area EA1. For example, an internal boundary of the reflective emission area EA2 may have an approximately circular ring shape and an outer periphery of the reflective emission area EA2 may have an uneven shape, such as an iris flower pattern, a zigzag pattern, or a wavy pattern.

Again, as illustrated in FIG. 5, FIGS. 6A and 6B, and FIG. 8, the anode electrode 121 may include a third area 121c extending from the second area 121b and having a surface that is substantially parallel to the surface of the second substrate 110b. The third area 121c may correspond to the upper surface of the third planarization layer 115c.

As described above, in one example sub-pixel, the second planarization layer 115b and the third planarization layer 115c may include at least one contact hole that is spaced apart from the first open area OA1. The driving transistor Td and the anode electrode 121 of the light emitting element 120 may be electrically connected through the contact hole.

The bank 116 may be disposed to cover the anode electrode 121.

The bank 116 may cover the second area 121b and the third area 121c of the anode electrode 121. Also, the bank 116 may cover a portion of the first area 121a of the anode electrode 121. For example, the bank 116 may partially cover an edge of the first area 121a of the anode electrode 121.

A portion of the bank 116 corresponding to the emission area of the sub-pixel may be open.

For example, the bank 116 may include the second open area OA2 in which a portion corresponding to the main emission area EA1 of each sub-pixel is removed (open). For example, the first open area OA1 may have a width greater than that of the second open area OA2. For example, when viewed in a planar perspective, the second open area OA2 may have a circular shape (see, e.g., FIG. 6B) but is not limited thereto. An edge of the second open area OA2 according to the present disclosure may have an uneven shape including an iris flower pattern, a zigzag pattern, or a wavy pattern, or a plurality of polygonal patterns, and may have various shapes, such as an elliptical shape or a rectangular shape.

In another aspect, the main emission area EA1 may have a shape corresponding to the shape of the second open area OA2. The fact that a shape of a certain component corresponds to a shape of another component means that a shape of a certain component is the same as that of another component, or a shape of a certain component is the same as that of another component but a size thereof differs from a size of another component, or a shape of a certain component is transferred to a shape of another component by any method. Accordingly, it can be understood that the shape of the main emission area EA1 is substantially obtained by transferring the shape of the second open area OA2 thereto by light emitted from an organic layer 122 located in the second open area OA2.

The reflective emission area EA2 does not overlap the main emission area EA1 and may be located to surround the main emission area EA1.

Also, the reflective emission area EA2 may be a closed curve surrounding the main emission area EA1. Alternatively, the reflective emission area EA2 may have a shape in which a portion of the closed curve is disconnected.

The sub-pixels may be distinguished by the main emission area EA1.

Next, the bank 116 may include an upper surface, a side portion, and a bottom portion.

For example, the upper surface of the bank 116 may be a surface that is located at an uppermost portion of the bank 116 and may be substantially parallel to the second substrate 110b.

Also, the upper surface of the bank 116 may correspond to the upper surface of the third planarization layer 115c.

The side portion of the bank 116 may be a surface extending from the upper surface of the bank 116 to form a side surface thereof. The side portion of the bank 116 may be tapered or inclined at a predetermined angle. For example, the side portion of the bank 116 may be tapered or inclined at an angle of 30° to 65° with respect to the upper surface of the bank 116, but the present disclosure is not limited thereto. The side portion of the bank 116 may correspond to the side portion of the third planarization layer 115c.

For example, the bottom portion of the bank 116 may correspond to a surface in contact with the anode electrode 121 at the first area 121a of the anode electrode 121. The bottom portion of the bank 116 may correspond to the non-emission area NEA between the main emission area EA1 and the reflective emission area EA2.

The first open area OA1 provided in the third planarization layer 115c may have a width greater than that of the second open area OA2 provided in the bank 116. Accordingly, the second open area OA2 may be located within the first open area OA1.

For example, a portion of the anode electrode 121 may be exposed by the second open area OA2.

The bank 116 may be formed of a polyimide (PI)-based material but is not limited thereto.

The side portion of the bank 116 may have a circular shape in the same manner as the edge of the second open area OA2 (see, e.g., FIG. 6B), but the present disclosure is not limited thereto. For example, the side portion of the bank 116 according to the present disclosure may have an uneven shape including an iris flower pattern, a zigzag pattern, a wavy pattern, or a plurality of polygonal patterns, and may have various shapes, such as an elliptical shape or a rectangular shape.

For example, the organic layer 122 may be disposed in and around the second open area OA2 of the bank 116. For example, the organic layer 122 may be disposed on the anode electrode 121 that is exposed through the second open area OA2 of the bank 116. For example, the organic layer 122 may be disposed in the second open area OA2 of the bank 116.

The organic layer 122 may be disposed only within the second open area OA2, but the present disclosure is not limited thereto. A portion of the organic layer 122 may be disposed on the upper surface and the side portion of the bank 116 other than the second open area OA2.

A cathode electrode 123 may be disposed on the organic layer 122.

In this manner, the light emitting element 120 may be configured by the anode electrode 121, the organic layer 122, and the cathode electrode 123.

For example, the main emission area EA1 may be formed by the light emitting element 120 that is provided in the second open area OA2.

An encapsulation layer (not illustrated) may be located on the light emitting element 120 described above.

The encapsulation layer may have a single-layer structure or a multilayer structure. For example, the encapsulation layer may include a first encapsulation layer, a second encapsulation layer, and a third encapsulation layer.

For example, the first encapsulation layer and the third encapsulation layer may be formed of an inorganic layer, and the second encapsulation layer may be formed of an organic layer. For example, among the first encapsulation layer, the second encapsulation layer, and the third encapsulation layer, the second encapsulation layer may be the thickest and may serve as a planarization layer.

The first encapsulation layer may be formed of an inorganic insulating material capable of low-temperature deposition and may be formed of, for example, silicon nitride (SiNx), silicon oxide (SiOx), silicon oxynitride (SiON), or aluminum oxide (Al₂O₃).

The second encapsulation layer may be formed to have an area smaller than that of the first encapsulation layer in a plan view. In this case, the second encapsulation layer may be formed to expose both ends of the first encapsulation layer.

Also, for example, the second encapsulation layer may be formed of an organic insulating material, such as acrylic resin, epoxy resin, polyimide, polyethylene, or silicon oxycarbon (SiOC). Also, for example, the second encapsulation layer may be formed through an inkjet method but is not limited thereto.

The third encapsulation layer may be formed to cover an upper surface and side surfaces of each of the second encapsulation layer and the first encapsulation layer.

For example, the third encapsulation layer may minimize or block penetration of external moisture or oxygen into the first encapsulation layer and the second encapsulation layer. Also, for example, the third encapsulation layer may be formed of an inorganic insulating material, such as silicon oxide (SiOx), silicon oxynitride (SiON), aluminum oxide (Al₂O₃), or silicon nitride (SiNx).

A touch sensor layer may be disposed on an upper portion of the encapsulation layer described above.

In another aspect, as described above, when viewed in a planar perspective, the side portion of the third planarization layer and the edge of the first open area according to the present disclosure may have an uneven shape including a plurality of polygonal patterns, which will be described in more detail with reference to the drawings.

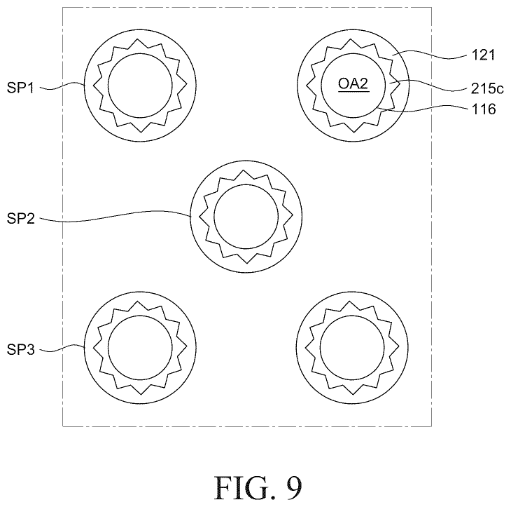

FIG. 9 is a view illustrating a sub-pixel structure of a second example embodiment of the present disclosure.

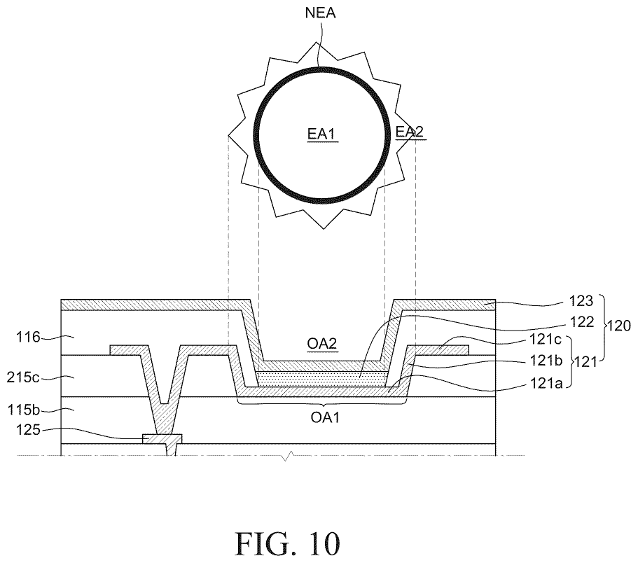

FIG. 10 is a view illustrating by way of example a light emission image of the second example embodiment of the present disclosure.

Since other configurations of the second example embodiment of the present disclosure in FIGS. 9 and 10 are substantially identical to those of the first example embodiment of the present disclosure described with reference to FIGS. 4 to 8, with only differences in shapes of a third planarization layer 215c and the first open area OA1, duplicate descriptions may be omitted below.

FIG. 9 shows a portion of a display panel on which five sub-pixels, including SP1, SP2, and SP3, are disposed, as an example, and shows by way of example the bank 116 including the second open area OA2 which is the main emission area, the anode electrode 121, and the third planarization layer 215c.

FIG. 10 illustrates by way of example a portion of a cross-section of one sub-pixel of the display panel according to the second example embodiment of the present disclosure and a light emission image corresponding thereto. In addition, in FIG. 10, an illustration of components above and below light emitting element 120 is omitted for convenience, but the present disclosure is not limited thereto. The present disclosure may include an encapsulation layer and a touch sensor layer over the light emitting element 120.

As illustrated in FIG. 9, the display panel according to the second example embodiment of the present disclosure may include a pixel area in which a plurality of sub-pixels SP1, SP2, and SP3 are present and may include a line area in which various signal lines are disposed.

The plurality of first sub-pixels SP1, second sub-pixels SP2, and third sub-pixels SP3 may be disposed in the pixel area.

For example, the first sub-pixel SP1 may be a red sub-pixel.

For example, the second sub-pixel SP2 may be a green sub-pixel.

For example, the third sub-pixel SP3 may be a blue sub-pixel.

For example, the first sub-pixel SP1, the second sub-pixel SP2, and the third sub-pixel SP3 may have circular shapes or polygonal shapes, but the present disclosure is not limited thereto. Here, the shapes of the sub-pixels SP1, SP2, and SP3 may be defined by shapes of the anode electrodes 121, but the present disclosure is not limited thereto.

FIG. 9 illustrates an example in which one first sub-pixel SP1, one second sub-pixel SP2, and one third sub-pixel SP3 are gathered to form one pixel, but the present disclosure is not limited thereto.

In another aspect, in the present disclosure, in addition to the main emission area, the reflective emission area may be added due to the side mirror (SM) structure of the anode electrode 121, so that each emission area can be expanded compared to each of the sub-pixels SP1, SP2, and SP3.

In addition, in the second example embodiment of the present disclosure, a side portion of the third planarization layer 215c in contact with the side surface of the anode electrode 121 having the side mirror structure may have an uneven shape including a plurality of triangular patterns, when viewed in a planar perspective. Accordingly, the area of the side mirror of the anode electrode 121 can be substantially increased. Thus, luminous efficiency can be improved, a luminance viewing angle can be improved, and Rainbow Mura in a concentric form can be reduced through irregular reflection. However, the present disclosure is not limited thereto, and the side portion of the third planarization layer 215c may have an uneven shape including other polygonal patterns, such as a plurality of quadrangular patterns and a plurality of pentagonal patterns.

As illustrated in FIG. 10, the connection electrode 125 may be disposed on the first planarization layer 115a.

The second planarization layer 115b may be disposed on the connection electrode 125.

The third planarization layer 215c may be disposed on the second planarization layer 115b.

For example, the third planarization layer 215c may include the first open area OA1 in which portions corresponding to the main emission area EA1, the reflective emission area EA2, and the non-emission area NEA of the sub-pixel are removed (open).

For example, when viewed in a planar perspective, the first open area OA1 may have an approximately circular shape in which an edge thereof has an uneven shape including a plurality of triangular patterns, but the present disclosure is not limited thereto. The edge of the first open area OA1 according to example embodiments of the present disclosure may have an uneven shape including other polygonal patterns, such as a plurality of quadrangular patterns and a plurality of pentagonal patterns.

The third planarization layer 215c may include an upper surface and a side surface.

The upper surface of the third planarization layer 215c is a surface of the third planarization layer 215c located at an uppermost portion and may be substantially parallel to the second substrate 110b.

In addition, the side portion of the third planarization layer 215c may be a surface extending laterally or diagonally from the upper surface of the third planarization layer 215c. For example, the side portion of the third planarization layer 215c may be tapered or inclined at a predetermined angle. For example, the side portion of the third planarization layer 215c may be tapered or inclined at an angle of 30° to 65° with respect to the upper surface of the third planarization layer 215c but is not limited thereto.

The side portion of the third planarization layer 215c may have an uneven shape including a plurality of triangular patterns in the same manner as the edge of the first open area OA1 when viewed in a planar perspective, but the present disclosure is not limited thereto. The side portion of the third planarization layer 215c according to example embodiments of the present disclosure may have an uneven shape including other polygonal patterns, such as a plurality of quadrangular patterns and a plurality of pentagonal patterns.

In another aspect, the anode electrode 121 may be disposed on the upper surface and the side portion of the third planarization layer 215c and on the second planarization layer 115b. For example, the anode electrode 121 may be disposed on the upper surface and the side portion of the third planarization layer 215c and in the first open area OA1.

Also, for example, the anode electrode 121 disposed in the first open area OA1 may contact the upper surface of the second planarization layer 115b.

In addition, for example, the anode electrode 121 may include a first area 121a in the first open area OA1 and having a surface that is substantially parallel to the surface of the second substrate 110b and may include a second area 121b extending from the first area 121a and having a predetermined angle with respect to the second substrate 110b. Also, for example, the first area 121a of the anode electrode 121 may correspond to the first open area OA1. For example, the second area 121b of the anode electrode 121 may correspond to the side portion of the third planarization layer 215c.

In example embodiments of the present disclosure, the second area 121b of the anode electrode 121 may be a portion having a side mirror shape and may constitute a side mirror (SM) structure. The SM structure of the anode electrode 121 may be formed in the first open area OA1. For example, the SM structure of the anode electrode 121 may form the reflective emission area EA2. For example, the reflective emission area EA2 follows an outline of the main emission area EA1 and may have an uninterrupted ring shape or a disconnected ring shape. In the case of the disconnected ring shape, it may be a shape which surrounds the outline of the main emission area EA1 but is disconnected in the middle thereof.

For example, in the case of the second example embodiment of the present disclosure, the main emission area EA1 may have an approximately circular shape, and the non-emission area NEA may have a shape of an approximately circular ring surrounding the main emission area EA1. For example, the internal boundary of the reflective emission area EA2 may have an approximately circular ring shape, and the outer periphery of the reflective emission area EA2 may have an uneven shape including a plurality of triangular patterns.

According to the second example embodiment of the present disclosure, since the side portion of the third planarization layer 215c has an uneven shape including a plurality of triangular patterns, the second area 121b of the anode electrode 121 deposited thereon may also have an uneven shape including a plurality of triangular patterns. Accordingly, as the area of the side mirror, that is, the second area 121b of the anode electrode 121 is increased, luminous efficiency can be improved, and a luminance viewing angle can be improved. However, the present disclosure is not limited thereto, and the second area 121b of the anode electrode 121 according to example embodiments of the present disclosure may have an uneven shape including other polygonal patterns, such as a plurality of quadrangular patterns and a plurality of pentagonal patterns.

As described above, the SM structure formed in the first open area OA1 may form the reflective emission area EA2. As a part of light emitted by the light emitting element 120 is reflected from the second area 121b of the anode electrode 121 by the SM structure, the reflective emission area EA2 having a ring shape may be formed. Accordingly, luminous efficiency can be improved.

Also, for example, the edge of the reflective emission area EA2 may have an uneven shape including a plurality of triangular patterns according to the shape of the side portion of the third planarization layer 215c. As described above, in the second example embodiment of the present disclosure, since the side portion of the third planarization layer 215c is formed to have an uneven shape including a plurality of triangular patterns, it is possible to reduce periodicity of the patterns and prevent Rainbow Mura in a concentric form through irregular reflection.

In another aspect, the anode electrode 121 may include the third area 121c extending from the second area 121b and having a surface that is substantially parallel to the surface of the second substrate 110b. The third area 121c may correspond to the upper surface of the third planarization layer 215c.

As described above, in one example sub-pixel, the second planarization layer 115b and the third planarization layer 215c may include at least one contact hole that is spaced apart from the first open area OA1. The driving transistor Td and the anode electrode 121 of the light emitting element 120 may be electrically connected through the contact hole.

The bank 116 may be disposed to cover the anode electrode 121.

The bank 116 may cover the second area 121b and the third area 121c of the anode electrode 121. Also, the bank 116 may cover a portion of the first area 121a of the anode electrode 121. For example, the bank 116 may partially cover an edge of the first area 121a of the anode electrode 121.

A portion of the bank 116 corresponding to the emission area of the sub-pixel may be open.

For example, the bank 116 may include the second open area OA2 in which a portion corresponding to the main emission area EA1 of each sub-pixel is removed (open). For example, the first open area OA1 may have a width greater than that of the second open area OA2. For example, when viewed in a planar perspective, the second open area OA2 may have a circular shape but is not limited thereto. The edge of the second open area OA2 according to example embodiments of the present disclosure may have an uneven shape including an iris flower pattern, a zigzag pattern, or a wavy pattern, or a plurality of polygonal patterns, and may have various shapes, such as an elliptical shape or a rectangular shape.

The bank 116 may include the upper surface, the side portion, and the bottom portion.

For example, the upper surface of the bank 116 may be a surface that is located at an uppermost portion of the bank 116 and may be substantially parallel to the second substrate 110b. Also, the upper surface of the bank 116 may correspond to the upper surface of the third planarization layer 215c.

The side portion of the bank 116 may be a surface extending from the upper surface of the bank 116 to form the side surface thereof. The side portion of the bank 116 may be tapered or inclined at a predetermined angle. For example, the side portion of the bank 116 may be tapered or inclined at an angle of 30° to 65° with respect to the upper surface of the bank 116, but the present disclosure is not limited thereto. The side portion of the bank 116 may correspond to the side portion of the third planarization layer 215c.

For example, the bottom portion of the bank 116 may correspond to the surface in contact with the anode electrode 121 at the first area 121a of the anode electrode 121. The bottom portion of the bank 116 may correspond to the non-emission area NEA between the main emission area EA1 and the reflective emission area EA2.

The first open area OA1 provided in the third planarization layer 215c may have a width greater than that of the second open area OA2 provided in the bank 116. Accordingly, the second open area OA2 may be located within the first open area OA1 in a plan view.

For example, a portion of the anode electrode 121 may be exposed by the second open area OA2.

The side portion of the bank 116 may have a circular shape in the same manner as the edge of the second open area OA2, but the present disclosure is not limited thereto. For example, the side portion of the bank 116 according to the present disclosure may have an uneven shape including an iris flower pattern, a zigzag pattern, a wavy pattern, or a plurality of polygonal patterns.

For example, the organic layer 122 may be disposed in and around the second open area OA2 of the bank 116. For example, the organic layer 122 may be disposed on the anode electrode 121 that is exposed through the second open area OA2 of the bank 116. For example, the organic layer 122 may be disposed in the second open area OA2 of the bank 116.

The organic layer 122 may be disposed only within the second open area OA2, but the present disclosure is not limited thereto. A portion of the organic layer 122 may be disposed on the upper surface and the side portion of the bank 116 other than the second open area OA2.

The cathode electrode 123 may be disposed on the organic layer 122.

In this manner, the light emitting element 120 may be configured by the anode electrode 121, the organic layer 122, and the cathode electrode 123.

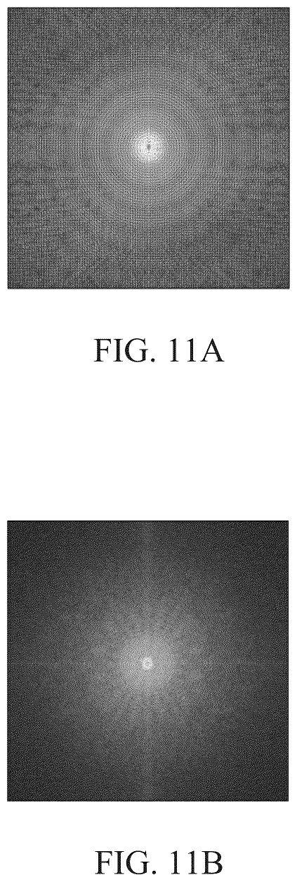

FIGS. 11A to 11C are example views showing unevenness images.

FIGS. 11A to 11C show by way of example unevenness images due to reflection of external light according to simulation.

FIG. 11A shows by way of example an unevenness image of a Comparative Example in which the side portion of the third planarization layer has a circular shape. In addition, FIG. 11B shows by way of example an unevenness image of the first example embodiment in which the side portion of the third planarization layer has an uneven shape, such as an iris flower pattern, a zigzag pattern, or a wavy pattern, and FIG. 11C shows by way of example an unevenness image of the second example embodiment in which the side portion of the third planarization layer has an uneven shape including a plurality of triangular patterns.

First, as shown in FIG. 11A, in the case of the Comparative Example in which the side portion of the third planarization layer has a circular shape, Rainbow Mura in a concentric form can be confirmed due to an interference phenomenon.

On the other hand, as shown in FIGS. 11B and 11C, in the case of the first example embodiment in which the side portion of the third planarization layer has an uneven shape, such as an iris flower pattern, a zigzag pattern, or a wavy pattern, and the second example embodiment in which the side portion of the third planarization layer has an uneven shape including a plurality of triangular patterns, circular interference was not confirmed.

As described above, in the case of the example embodiments of the present disclosure, Rainbow Mura in a concentric form can be prevented through irregular reflection by reducing periodicity of the patterns at an edge of the side portion of the third planarization layer.

In another aspect, as the number of pixels per inch (PPI) increases, rates of increase in luminous efficiency and luminance viewing angle can further increase, which will be described in more detail with reference to the following drawings.

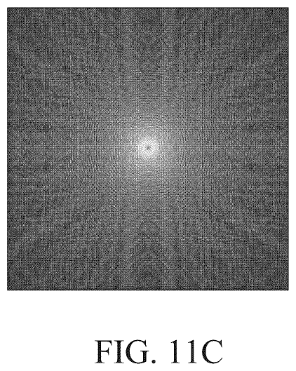

FIGS. 12A to 12C are example graphs showing luminous efficiency according to pixels per inch (PPI).

FIGS. 12A to 12C show simulation results for sub-pixels having a square shape, for example.

FIG. 12A is an example graph showing luminous efficiency according to PPI for a red sub-pixel, and FIG. 12B is an example graph showing luminous efficiency according to PPI for a green sub-pixel. In addition, FIG. 12C is an example graph showing luminous efficiency according to PPI for a blue sub-pixel.

FIGS. 12A to 12C respectively show degrees of luminous efficiency of Comparative Examples (Ref_) without the SM structure and experimental example embodiments with the SM structure (SM_), in cases where the pixels per inch (PPL) are 150, 250, 350, and 450 PPI.

For example, 150_Ref_R indicates a red sub-pixel of the Comparative Example to which the SM structure is not applied in the case of 150 PPI, and 150_SM_R indicates a red sub-pixel of an example embodiment to which the SM structure is applied in the case of 150 PPI.

For example, 150_Ref_G indicates a green sub-pixel of the Comparative Example to which the SM structure is not applied in the case of 150 PPI, and 150_SM_G indicates a green sub-pixel of the example embodiment to which the SM structure is applied in the case of 150 PPI.

For example, 150_Ref_B indicates a blue sub-pixel of the Comparative Example to which the SM structure is not applied in the case of 150 PPI, and 150_SM_B indicates a blue sub-pixel of the example embodiment to which the SM structure is applied in the case of 150 PPI.

As illustrated in FIG. 12A, in the case of 150 PPI, it can be seen that the luminous efficiency of the red sub-pixel 150_Ref_R of the Comparative Example is about 49.8527 cd/A on average whereas the luminous efficiency of the red sub-pixel 150_SM_R of the example embodiment is about 52.3717 cd/A on average, which is an improvement over the Comparative Example by about 5.1%.

In addition, in the case of 250 PPI, it can be seen that the luminous efficiency of the red sub-pixel 250_Ref_R of the Comparative Example is about 50.4407 cd/A on average whereas the luminous efficiency of the red sub-pixel 250_SM_R of the example embodiment is about 52.4882 cd/A on average, which is an improvement over the Comparative Example by about 4.6%.

In addition, in the case of 350 PPI, it can be seen that the luminous efficiency of the red sub-pixel 350_Ref_R of the Comparative Example is about 50.2562 cd/A on average whereas the luminous efficiency of the red sub-pixel 350_SM_R of the example embodiment is about 55.0394 cd/A on average, which is an improvement over the Comparative Example by about 9.5%.

In addition, in the case of 450 PPI, it can be seen that the luminous efficiency of the red sub-pixel 450_Ref_R of the Comparative Example is about 50.7684cd/A on average whereas the luminous efficiency of the red sub-pixel 450_SM_R of the example embodiment is about 54.6435cd/A on average, which is an improvement over the Comparative Example by about 7.6%.

As illustrated in FIG. 12B, in the case of 150 PPI, it can be seen that the luminous efficiency of the green sub-pixel 150_Ref_G of the Comparative Example is about 146.706 cd/A on average whereas the luminous efficiency of the green sub-pixel 150_SM_G of the example embodiment is about 156.012 cd/A on average, which is an improvement over the Comparative Example by about 6.3%.

In addition, in the case of 250 PPI, it can be seen that the luminous efficiency of the green sub-pixel 250_Ref_G of the Comparative Example is about 149.02 cd/A on average whereas the luminous efficiency of the green sub-pixel 250_SM_G of the example embodiment is about 158.259 cd/A on average, which is an improvement over the Comparative Example by about 6.2%.

In addition, in the case of 350 PPI, it can be seen that the luminous efficiency of the green sub-pixel 350_Ref_G of the Comparative Example is about 150.28 cd/A on average whereas the luminous efficiency of the green sub-pixel 350_SM_G of the example embodiment is about 169.813 cd/A on average, which is an improvement over the Comparative Example by about 13.0%.

In addition, in the case of 450 PPI, it can be seen that the luminous efficiency of the green sub-pixel 450_Ref_G of the Comparative Example is about 150.331 cd/A on average whereas the luminous efficiency of the green sub-pixel 450_SM_G of the example embodiment is about 169.797 cd/A on average, which is an improvement over the Comparative Example by about 12.9%.

As illustrated in FIG. 12C, in the case of 150 PPI, it can be seen that the luminous efficiency of the blue sub-pixel 150_Ref_B of the Comparative Example is about 8.0649 cd/A on average whereas the luminous efficiency of the blue sub-pixel 150_SM_B of the example embodiment is about 8.38845 cd/A on average, which is an improvement over the Comparative Example by about 4.0%.

In addition, in the case of 250 PPI, it can be seen that the luminous efficiency of the blue sub-pixel 250_Ref_B of the Comparative Example is about 8.17111 cd/A on average whereas the luminous efficiency of the blue sub-pixel 250_SM_B of the example embodiment is about 8.7342 cd/A on average, which is an improvement over the Comparative Example by about 6.9%.

In addition, in the case of 350 PPI, it can be seen that the luminous efficiency of the blue sub-pixel 350_Ref_B of the Comparative Example is about 8.2944 cd/A on average whereas the luminous efficiency of the blue sub-pixel 350_SM_B of the example embodiment is about 9.44055 cd/A on average, which is an improvement over the Comparative Example by about 13.8%.

In addition, in the case of 450 PPI, it can be seen that the luminous efficiency of the blue sub-pixel 450_Ref_B of the Comparative Example is about 8.26757 cd/A on average whereas the luminous efficiency of the blue sub-pixel 450_SM_B of the example embodiment is about 9.64599 cd/A on average, which is an improvement over the Comparative Example by about 16.7%.

As described above, it can be seen that the rate of increase in luminous efficiency increases as the number of pixels per inch (PPI) increases, and this tendency is more prominent in example embodiments of the present disclosure to which the SM structure is applied. In addition, in the case of example embodiments of the present disclosure to which the SM structure is applied, it can be seen that the luminous efficiency is increased regardless of the number of pixels per inch (PPI) compared to the Comparative Examples.

In addition, although not shown, the luminance viewing angles of the example embodiments of the present disclosure are increased compared to the Comparative Examples under high PPI conditions.

In another aspect, as described above, when viewed in a planar perspective, the side portion of the bank and the edge of the second open area may have a rectangular shape, which will be described in more detail with reference to the drawings.

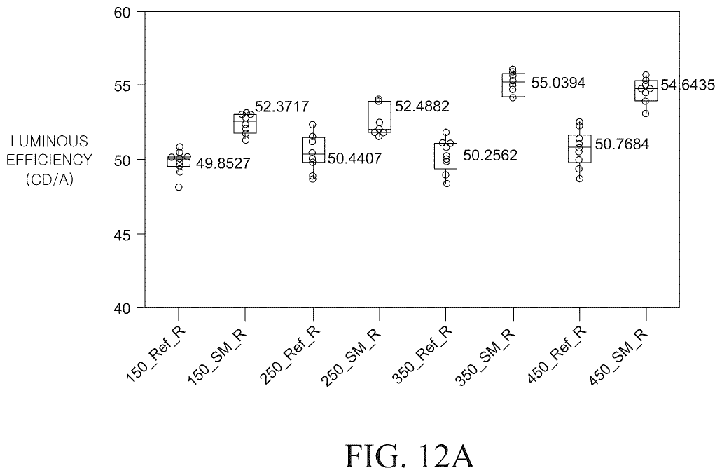

FIG. 13 is a view illustrating a sub-pixel structure of a third example embodiment of the present disclosure.

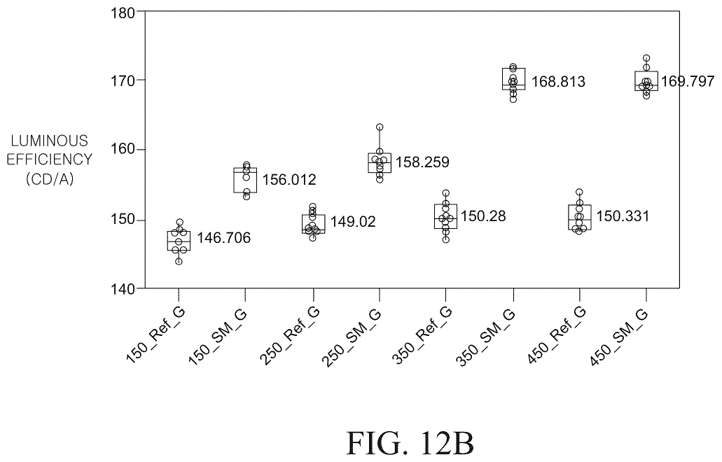

FIG. 14 is a view illustrating by way of example a light emission image of the third example embodiment of the present disclosure.

Since other configurations of the third example embodiment of the present disclosure in FIGS. 13 and 14 are substantially identical to those of the first example embodiment of the present disclosure described with reference to FIGS. 4 to 8, with only differences in shapes of a third planarization layer 315c, the first open area OA1, a bank 316, and the second open area OA2, duplicate descriptions may be omitted below.

FIG. 13 shows a portion of an example display panel on which five sub-pixels, including SP1, SP2, and SP3, are disposed. FIG. 3 also shows by way of example the bank 316 including the second open area OA2, which is the main emission area, an anode electrode 321, and the third planarization layer 315c.

As illustrated in FIGS. 13 and 14, the display panel according to the third example embodiment of the present disclosure may include a pixel area in which a plurality of sub-pixels SP1, SP2, and SP3 are present and may include a line area in which various signal lines are disposed.

The plurality of first sub-pixels SP1, second sub-pixels SP2, and third sub-pixels SP3 may be disposed in the pixel area.

For example, the first sub-pixel SP1 may be a red sub-pixel.

For example, the second sub-pixel SP2 may be a green sub-pixel.

For example, the third sub-pixel SP3 may be a blue sub-pixel.

For example, the first sub-pixel SP1, the second sub-pixel SP2, and the third sub-pixel SP3 may have an approximately elliptical shape, but the present disclosure is not limited thereto. Here, the shapes of the sub-pixels SP1, SP2, and SP3 may be defined by shapes of the anode electrodes 321, but the present disclosure is not limited thereto.

FIG. 13 illustrates an example in which one first sub-pixel SP1, one second sub-pixel SP2, and one third sub-pixel SP3 are gathered to form one pixel, but the present disclosure is not limited thereto.

In another aspect, in the present disclosure, in addition to the main emission area EA1, the reflective emission area EA2 may be added due to a side mirror (SM) structure of the anode electrode 321, so that each emission area can be expanded compared to each of the sub-pixels SP1, SP2, and SP3.

For example, in the case of the third example embodiment of the present disclosure, the main emission area EA1 may have an approximately rectangular shape, and the non-emission area NEA may have a shape of an approximately rectangular ring surrounding the main emission area EA1. For example, the inner boundary of the reflective emission area EA2 may have an approximately rectangular ring shape, and the outer periphery of the reflective emission area EA2 may have an uneven shape, such as an iris flower pattern, a zigzag pattern, or a wavy pattern.

In addition, in the third example embodiment of the present disclosure, a side portion of the third planarization layer 315c in contact with a side surface of the anode electrode 321 having the side mirror structure may have an uneven shape, such as an iris flower pattern, a zigzag pattern, or a wavy pattern, when viewed in a planar perspective. Accordingly, an area of a side mirror of the anode electrode 321 can be substantially increased. Thus, luminous efficiency can be improved, a luminance viewing angle can be improved, and Rainbow Mura in a concentric form can be reduced through irregular reflection. However, the present disclosure is not limited thereto, and the side portion of the third planarization layer 315c may have an uneven shape including a plurality of polygonal patterns.

For example, the third planarization layer 315c may include the first open area OA1 in which portions corresponding to the main emission area EA1, the reflective emission area EA2, and the non-emission area NEA of the sub-pixel are removed (open).

For example, when viewed in a planar perspective, the first open area OA1 may have an approximately rectangular or oval shape in which an edge thereof has an uneven shape, such as an iris flower pattern, a zigzag pattern, or a wavy pattern, but the present disclosure is not limited thereto. For example, the edge of the first open area OA1 according to the present disclosure may have an uneven shape including a plurality of polygonal patterns.

The third planarization layer 315c may include an upper surface and a side surface.

The upper surface of the third planarization layer 315c may be a surface of the third planarization layer 315c located at an uppermost portion and may be substantially parallel to the second substrate.

In addition, the side portion of the third planarization layer 315c may be a surface extending laterally or diagonally from the upper surface of the third planarization layer 315c. For example, the side portion of the third planarization layer 315c may be tapered or inclined at a predetermined angle. For example, the side portion of the third planarization layer 315c may be tapered or inclined at an angle of 30° to 65° with respect to the upper surface of the third planarization layer 315c, but is not limited thereto.

The side portion of the third planarization layer 315c may have an uneven shape, such as an iris flower pattern, a zigzag pattern, or a wavy pattern in the same manner as the edge of the first open area OA1 when viewed in a planar perspective, but the present disclosure is not limited thereto. The side portion of the third planarization layer 315c according to example embodiments of the present disclosure may have an uneven shape including a plurality of polygonal patterns.

The anode electrode 321 may be disposed on the upper surface and the side portion of the third planarization layer 315c and the first open area OA1.

According to the third example embodiment of the present disclosure, since the side portion of the third planarization layer 315c has an uneven shape, such as an iris flower pattern, a zigzag pattern, or a wavy pattern, a second area of the anode electrode 321 deposited thereon may also have an uneven shape, such as an iris flower pattern, a zigzag pattern, or a wavy pattern. However, the present disclosure is not limited thereto, and the second area of the anode electrode 321 according to the present disclosure may have an uneven shape including a plurality of polygonal patterns.

The bank 316 may be disposed to cover the anode electrode 321.

A portion of the bank 316 corresponding to the emission area of the sub-pixel may be open.

For example, the bank 316 may include the second open area OA2 in which a portion corresponding to the main emission area EA1 of each sub-pixel is removed (open). For example, the first open area OA1 may have a width greater than that of the second open area OA2. For example, when viewed in a planar perspective, the second open area OA2 may have a rectangular shape, but the present disclosure is not limited thereto. For example, the second open area OA2 of the present disclosure may have other polygonal shapes, such as a triangular shape or a pentagonal shape.

The bank 316 may include an upper surface, a side portion, and a bottom portion.

For example, the upper surface of the bank 316 may be a surface that is located at an uppermost portion of the bank 316 and may be substantially parallel to the second substrate. Also, the upper surface of the bank 316 may correspond to the upper surface of the third planarization layer 315c.

The side portion of the bank 316 may be a surface extending from the upper surface of the bank 316 to form a side surface thereof. The side portion of the bank 316 may be tapered or inclined at a predetermined angle. For example, the side portion of the bank 316 may be tapered or inclined at an angle of 30° to 65° with respect to the upper surface of the bank 316, but the present disclosure is not limited thereto. The side portion of the bank 316 may correspond to the side portion of the third planarization layer 315c.

In addition, for example, the bottom portion of the bank 316 may correspond to a surface in contact with the anode electrode 321 at a first area of the anode electrode 321. The bottom portion of the bank 316 may correspond to the non-emission area NEA between the main emission area EA1 and the reflective emission area EA2.

The first open area OA1 provided in the third planarization layer 315c may have a width greater than that of the second open area OA2 provided in the bank 316. Accordingly, the second open area OA2 may be located within the first open area OA1 in a plan view.

For example, a portion of the anode electrode 321 may be exposed by the second open area OA2.

The side portion of the bank 316 may have a rectangular shape in the same manner as the edge of the second open area OA2 when viewed in a planar perspective, but the present disclosure is not limited thereto. For example, the side portion of the bank 316 according to example embodiments of the present disclosure may have another polygonal shape, such as a triangular shape, a pentagonal shape, or the like.

As described above, when viewed in a plan view, the side portion of the bank and the edge of the second open area may have an uneven shape, such as an iris flower pattern, a zigzag pattern, or a wavy pattern, which will be described in more detail with reference to the drawings.

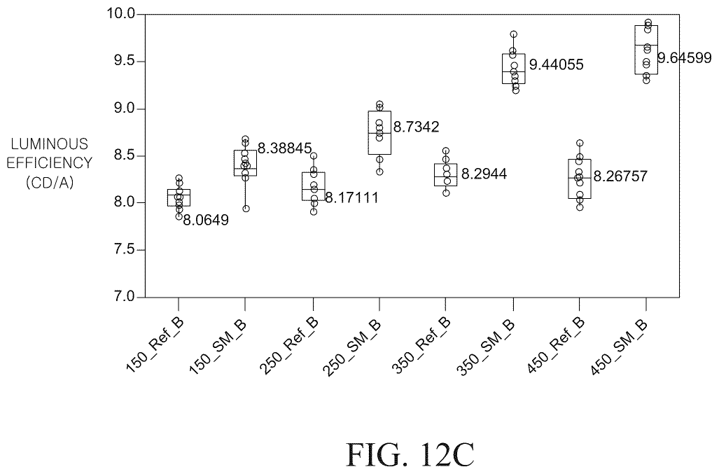

FIG. 15 is a view illustrating a sub-pixel structure according to a fourth example embodiment of the present disclosure.

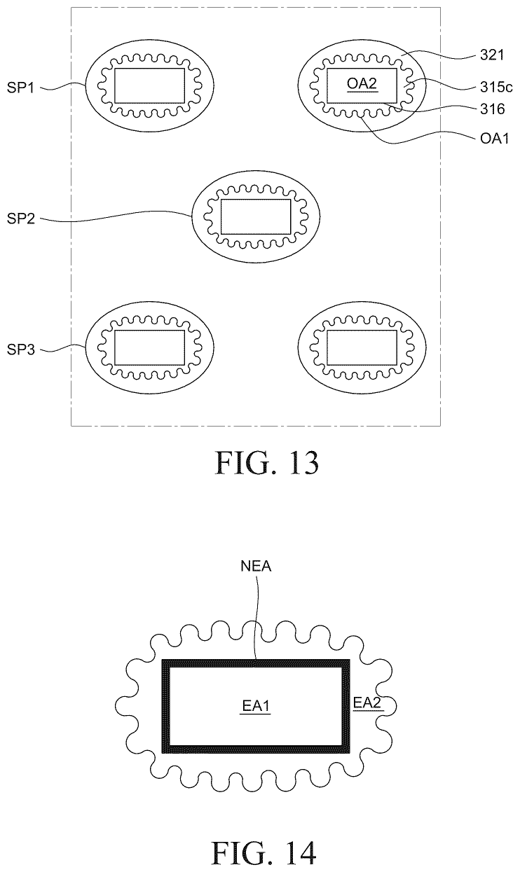

FIG. 16 is a view illustrating by way of example a light emission image of the fourth example embodiment of the present disclosure.

Since other configurations of the fourth example embodiment of the present disclosure in FIGS. 15 and 16 are substantially identical to those of the first example embodiment of the present disclosure described with reference to FIGS. 4 to 8, with only differences in shapes of a bank 416 and the second open area OA2, duplicate descriptions may be omitted below.

FIG. 15 shows a portion of an example display panel on which five sub-pixels, including SP1, SP2, and SP3 are disposed. FIG. 15 shows by way of example the bank 416 including the second open area OA2, which is the main emission area, the anode electrode 121, and the third planarization layer 115c.

As illustrated in FIGS. 15 and 16, the display panel according to the fourth example embodiment of the present disclosure may include a pixel area in which a plurality of sub-pixels SP1, SP2, and SP3 are present and may include a line area in which various signal lines are disposed.

The plurality of first sub-pixels SP1, second sub-pixels SP2, and third sub-pixels SP3 may be disposed in the pixel area.

For example, the first sub-pixel SP1, the second sub-pixel SP2, and the third sub-pixel SP3 may have an approximately circular shape, but the present disclosure is not limited thereto.

As described above, in example embodiments of the present disclosure, in addition to the main emission area EA1, the reflective emission area EA2 may be added due to the side mirror (SM) structure of the anode electrode 121, so that each emission area can be expanded, compared to each of the sub-pixels SP1, SP2, and SP3.

For example, in the case of the fourth example embodiment of the present disclosure, the main emission area EA1 may have an approximately circular shape in which an edge thereof has an uneven shape, such as an iris flower pattern, a zigzag pattern, or a wavy pattern. In addition, the non-emission area NEA may have a shape of an approximately circular ring surrounding the main emission area EA1, and an inner boundary and an outer periphery of the non-emission area NEA may have an uneven shape, such as an iris flower pattern, a zigzag pattern, or a wavy pattern. In addition, the reflective emission area EA2 may have a shape of an approximately circular ring surrounding the non-emission area NEA, and an inner boundary and an outer periphery of the reflective emission area EA2 may have an uneven shape, such as an iris flower pattern, a zigzag pattern, or a wavy pattern.

In the fourth example embodiment of the present disclosure, the side portion of the third planarization layer 115c in contact with the side surface of the anode electrode 121 having the side mirror structure may have an uneven shape, such as an iris flower pattern, a zigzag pattern, or wavy pattern, when viewed in a planar perspective. However, the present disclosure is not limited thereto. For example, the side portion of the third planarization layer 115c may have an uneven shape including a plurality of polygonal patterns.

For example, the third planarization layer 115c may include the first open area OA1 in which portions corresponding to the main emission area EA1, the reflective emission area EA2, and the non-emission area NEA of the sub-pixel are removed (open).

For example, when viewed in a planar perspective, the first open area OA1 may be formed such that an edge thereof has an uneven shape, such as an iris flower pattern, a zigzag pattern, or a wavy pattern, but the present disclosure is not limited thereto. For example, the edge of the first open area OA1 according to example embodiments of the present disclosure may have an uneven shape including a plurality of polygonal patterns.

The bank 416 may be disposed to cover the anode electrode 121.

A portion of the bank 416 corresponding to the emission area of the sub-pixel may be open.

For example, the bank 416 may include the second open area OA2 in which a portion corresponding to the main emission area EA1 of each sub-pixel is removed (open). For example, the first open area OA1 may have a width greater than that of the second open area OA2. For example, when viewed in a planar perspective, the second open area OA2 may have an approximately circular shape in which an edge thereof has an uneven shape, such as an iris flower pattern, a zigzag pattern, or a wavy pattern, but the present disclosure is not limited thereto. For example, the edge of the second open area OA2 according to example embodiments the present disclosure may have an uneven shape including a plurality of polygonal shapes.

The bank 416 may include an upper surface, a side portion, and a bottom portion.

For example, the upper surface of the bank 416 may be a surface that is located at an uppermost portion of the bank 416 and may be substantially parallel to the second substrate. Also, the upper surface of the bank 416 may correspond to the upper surface of the third planarization layer 115c.

The side portion of the bank 416 may be a surface extending from the upper surface of the bank 416 to form a side surface thereof. The side portion of the bank 416 may be tapered or inclined at a predetermined angle. For example, the side portion of the bank 416 may be tapered or inclined at an angle of 30° to 65° with respect to the upper surface of the bank 416, but the present disclosure is not limited thereto. The side portion of the bank 416 may correspond to the side portion of the third planarization layer 115c.

In addition, for example, the bottom portion of the bank 416 may correspond to a surface in contact with the anode electrode 121 at the first area of the anode electrode 121. The bottom portion of the bank 416 may correspond to the non-emission area NEA between the main emission area EA1 and the reflective emission area EA2.

When viewed in a planar perspective, the side portion of the bank 416 may have an approximately circular shape in which the edge thereof has an uneven shape, such as an iris flower pattern, a zigzag pattern, or a wavy pattern, in the same manner as the second open area OA2, but the present disclosure is not limited thereto. For example, the side portion of the bank 416 according to example embodiments of the present disclosure may have an uneven shape including a plurality of polygonal patterns.

As described above, when viewed in a planar perspective, the side portion of the third planarization layer and the edge of the first open area OA1, the side portion of the bank and the edge of the second open area OA2 according to example embodiments the present disclosure may have uneven shapes including a plurality of polygonal patterns, which will be described in more detail with reference to the drawings.

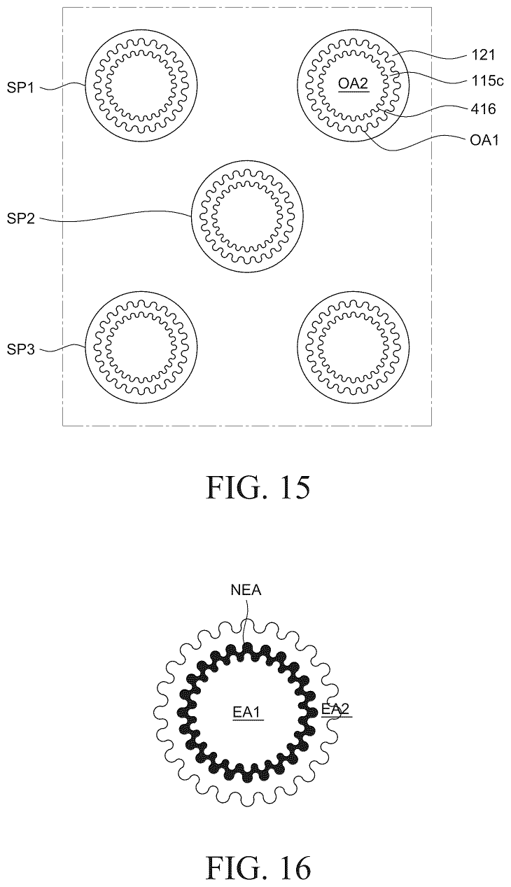

FIG. 17 is a view illustrating a sub-pixel structure according to a fifth example embodiment of the present disclosure.

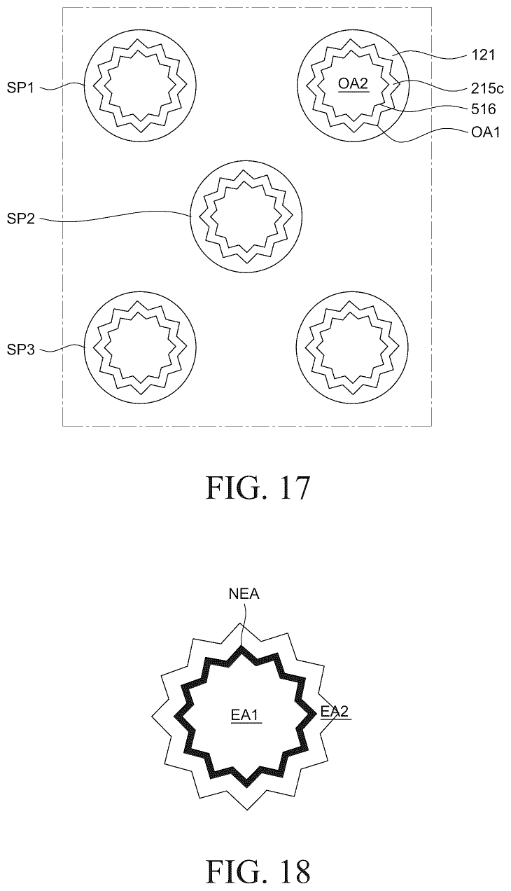

FIG. 18 is a view illustrating by way of example a light emission image of the fifth example embodiment of the present disclosure.

Since other configurations of the fifth example embodiment of the present disclosure in FIGS. 17 and 18 are substantially identical to those of the second example embodiment of the present disclosure in FIGS. 9 and 10 described above, with only differences in shapes of a bank 516 and the second open area OA2, duplicate descriptions may be omitted.

FIG. 17 shows a portion of an example display panel on which five sub-pixels, including SP1, SP2, and SP3, are disposed. FIG. 17 shows by way of example the bank 516 including the second open area OA2, which is a main emission area, the anode electrode 121, and the third planarization layer 215c.

As illustrated in FIGS. 17 and 18, the display panel according to the fifth example embodiment of the present disclosure may include a pixel area in which a plurality of sub-pixels SP1, SP2, and SP3 are present and may include a line area in which various signal lines are disposed.

The plurality of first sub-pixels SP1, second sub-pixels SP2, and third sub-pixels SP3 may be disposed in the pixel area.

For example, the first sub-pixel SP1, the second sub-pixel SP2, and the third sub-pixel SP3 may have an approximately circular shape but are not limited thereto.

As described above, in example embodiments of the present disclosure, in addition to the main emission area EA1, the reflective emission area EA2 may be added due to the side mirror (SM) structure of the anode electrode 121, so that each emission area can be expanded, compared to each of the sub-pixels SP1, SP2, and SP3.

For example, in the case of the fifth example embodiment of the present disclosure, the main emission area EA1 may have an approximately circular shape in which an edge thereof has an uneven shape including a plurality of triangular patterns. In addition, the non-emission area NEA may have a shape of an approximately circular ring surrounding the main emission area EA1, and the inner and outer boundaries of the non-emission area NEA may have an uneven shape including a plurality of triangular patterns. In addition, the reflective emission area EA2 may have a shape of an approximately circular ring surrounding the non-emission area NEA, and the inner and outer boundaries of the reflective emission area EA2 may have an uneven shape including a plurality of triangular patterns.

In the fifth example embodiment of the present disclosure, the side portion of the third planarization layer 215c in contact with the side surface of the anode electrode 121 having the side mirror structure may have an uneven shape including a plurality of triangular patterns, when viewed in a planar perspective. However, the present disclosure is not limited thereto. For example, the side portion of the third planarization layer 215c may have an uneven shape including a plurality of polygonal patterns, such as a plurality of quadrangular patterns and a plurality of pentagonal patterns.

For example, the third planarization layer 215c may include the first open area OA1 in which portions corresponding to the main emission area EA1, the reflective emission area EA2, and the non-emission area NEA of the sub-pixel are removed (open).

For example, when viewed in a planar perspective, the first open area OA1 may have an approximately circular shape in which an edge thereof has an uneven shape including a plurality of triangular patterns, but the present disclosure is not limited thereto. The edge of the first open area OA1 according to example embodiments of the present disclosure may have an uneven shape including other polygonal patterns, such as a plurality of quadrangular patterns and a plurality of pentagonal patterns.

The bank 516 may be disposed to cover the anode electrode 121.

A portion of the bank 516 corresponding to the emission area of the sub-pixel may be open.

For example, the bank 516 may include the second open area OA2 in which a portion corresponding to the main emission area EA1 of each sub-pixel is removed (open). For example, the first open area OA1 may have a width greater than that of the second open area OA2. For example, when viewed in a planar perspective, the second open area OA2 may have an approximately circular shape in which an edge thereof has an uneven shape including a plurality of triangular patterns, but the present disclosure is not limited thereto. For example, the edge of the second open area OA2 according to example embodiments of the present disclosure may have an uneven shape including other polygonal patterns, such as a plurality of quadrangular patterns and a plurality of pentagonal patterns.

The bank 516 may include an upper surface, a side portion, and a bottom portion.

For example, the upper surface of the bank 516 may be a surface that is located at an uppermost portion of the bank 516 and may be substantially parallel to the second substrate. Also, the upper surface of the bank 516 may correspond to the upper surface of the third planarization layer 215c.

The side portion of the bank 516 may be a surface extending from the upper surface of the bank 516 to form a side surface thereof. The side portion of the bank 516 may be tapered or inclined at a predetermined angle. For example, the side portion of the bank 516 may be tapered or inclined at an angle of 30° to 65° with respect to the upper surface of the bank 516, but the present disclosure is not limited thereto. The side portion of the bank 516 may correspond to the side portion of the third planarization layer 215c.

In addition, for example, the bottom portion of the bank 516 may correspond to a surface in contact with the anode electrode 121 at the first area of the anode electrode 121. The bottom portion of the bank 516 may correspond to the non-emission area NEA between the main emission area EA1 and the reflective emission area EA2.

When viewed in a planar perspective, the side portion of the bank 516 may have an approximately circular shape in which the edge thereof has an uneven shape including a plurality of triangular patterns in the same manner as the second open area OA2, but the present disclosure is not limited thereto. For example, the side portion of the bank 516 according to example embodiments of the present disclosure may have an uneven shape including other polygonal patterns, such as a plurality of quadrangular patterns and a plurality of pentagonal patterns.

In another aspect, the sub-pixels of example embodiments of the present disclosure may have different shapes. Accordingly, the anode electrode, the first open area, and the second open area may have different shapes therein, which will be described in more detail with reference to the drawings.

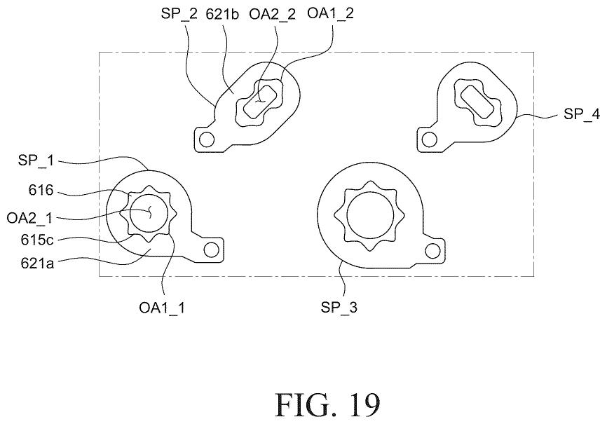

FIG. 19 is a view illustrating a sub-pixel structure according to a sixth example embodiment of the present disclosure.

The configurations of the sixth example embodiment of the present disclosure in FIG. 19 may be substantially identical to those of the aforementioned example embodiments of the present disclosure, with only differences being that sub-pixels SP_1, SP_2, SP_3, and SP_4 having different shapes are configured. Thus, duplicate descriptions may be omitted.

FIG. 19 illustrates a portion of an example display panel on which four sub-pixels SP_1, SP_2, SP_3, and SP_4 may be disposed. FIG. 19 shows by way of example a bank 616 including second open areas OA2_1 and OA2_2, anode electrodes 621a and 621b, and a third planarization layer 615c.

In FIG. 19, for convenience of description, only parts of components of a first type sub-pixel SP_1 and a second type sub-pixel SP_2 will be described with reference numerals.

As illustrated in FIG. 19, the display panel according to the sixth example embodiment of the present disclosure may include a pixel area in which a plurality of sub-pixels SP_1, SP_2, SP_3, and SP_4 are present and may include a line area in which various signal lines are disposed.

For example, a plurality of first type sub-pixels SP_1, second type sub-pixels SP_2, third type sub-pixels SP_3, and fourth type sub-pixels SP_4 may be disposed in the pixel area.

The plurality of the first type sub-pixels SP_1, the second type sub-pixels SP_2, the third type sub-pixels SP_3, and the fourth type sub-pixels SP_4 may have different shapes but may otherwise have substantially the same configuration.

For example, the first type sub-pixel SP_1 may be a red, green, or blue sub-pixel.

For example, the second type sub-pixel SP_2 may be a red, green, or blue sub-pixel.

For example, the third type sub-pixel SP_3 may be a red, green, or blue sub-pixel.

For example, the fourth type sub-pixel SP_4 may be a red, green, or blue sub-pixel.

For example, the first type the sub-pixel SP_1 and the third type the sub-pixel SP_3 may have an approximately circular shape but are not limited thereto.

For example, the second type sub-pixel SP_2 and the fourth type sub-pixel SP_4 may have an approximately elliptical or rectangular shape, but are not limited thereto.

Here, the shapes of the sub-pixels SP_1, SP_2, SP_3, and SP_4 may be defined by shapes of the anode electrodes 621a and 621b, but are not limited thereto.

In another aspect, in example embodiments of the present disclosure, the anode electrodes 621a and 621b may have a side mirror (SM) structure. Accordingly, a reflective emission area may be added in addition to a main emission area, and each emission area can be expanded compared to each of the sub-pixels SP_1, SP_2, SP_3, and SP_4.

In the sixth example embodiment of the present disclosure, the first type sub-pixel SP_1 may include a first anode electrode 621a, and the second type sub-pixel SP_2 may include a second anode electrode 621b.

For example, the third planarization layer 615c may include first open areas OA1_1 and OA1_2 in which portions corresponding to the main emission areas, the reflective emission areas, and the non-emission areas of the sub-pixels are removed (open). The first open areas OA1_1 and OA1_2 may include a first-first open area OA1_1 of the first type sub-pixel SP_1 and a second-first open area OA1_2 of the second type sub-pixel SP_2.

When viewed in a planar perspective, the first-first open area OA1_1 may have an approximately circular shape, and an edge thereof may have an uneven shape, such as an iris flower pattern, a zigzag pattern, or a wavy pattern, but the present disclosure is not limited thereto. For example, the edge of the first-first open area OA1_1 may have an uneven shape including a plurality of polygonal patterns.

Also, when viewed in a planar perspective, the second-first open area OA1_2 may have an approximately elliptical or rectangular shape, and an edge thereof may have an uneven shape, such as an iris flower pattern, a zigzag pattern, or a wavy pattern, but the present disclosure is not limited thereto. For example, the edge of the second-first open area OA1_2 may have an uneven shape including a plurality of polygonal patterns.

Also, for example, in the first type sub-pixel SP_1, one side portion of the third planarization layer 615c facing the first-first open area OA1_1 may have an uneven shape, such as an iris flower pattern, a zigzag pattern, or a wavy pattern, in the same manner as the edge of the first-first open area OA1_1, when viewed in a planar perspective. However, the present disclosure is not limited thereto. One side portion of the third planarization layer 615c may have an uneven shape including a plurality of polygonal patterns.

Also, for example, in the second type sub-pixel SP_2, another side portion of the third planarization layer 615c facing the second-first open area OA1_2 may have an uneven shape, such as an iris flower pattern, a zigzag pattern, or a wavy pattern, in the same manner as the edge of the second-first open area OA1_2, when viewed in a planar perspective. However, the present disclosure is not limited thereto. Another side portion of the third planarization layer 615c may have an uneven shape including a plurality of polygonal patterns.

According to the sixth example embodiment of the present disclosure, since one side portion of the third planarization layer 615c has an uneven shape, such as an iris flower pattern, a zigzag pattern, or a wavy pattern, a second area of the first anode electrode 621a deposited thereon may also have an uneven shape, such as iris patterns, a zigzag pattern, or a wavy pattern, when viewed in a planar perspective. However, the present disclosure is not limited thereto, and the second area of the first anode electrode 621a according to the present disclosure may have an uneven shape including a plurality of polygonal patterns.

According to the sixth example embodiment of the present disclosure, since another side portion of the third planarization layer 615c has an uneven shape, such as iris patterns, a zigzag pattern, or a wavy pattern, a second area of the second anode electrode 621b deposited thereon may also have an uneven shape, such as an iris flower pattern, a zigzag pattern, or a wavy pattern, when viewed in a planar perspective. However, the present disclosure is not limited thereto, and the second area of the second anode electrode 621b according to example embodiments of the present disclosure may have an uneven shape including a plurality of polygonal patterns.

For example, the bank 616 may include second open areas OA2_1 and OA2_2 in which portions corresponding to the main emission area of each of the sub-pixels SP_1, SP_2, SP_3, and SP_4 are removed (open). For example, the first open areas OA1_1 and OA1_2 may have widths greater than those of the second open areas OA2_1 and OA2_2, respectively. The second open areas OA2_1 and OA2_2 may include a first-second open area OA2_1 of the first type sub-pixel SP_1 and a second-second open area OA2_2 of the second type sub-pixel SP_2.

When viewed in a planar perspective, the first-second open area OA2_1 may have an approximately circular shape, in which an edge thereof may have an uneven shape, such as an iris flower pattern, a zigzag pattern, or a wavy pattern, but the present disclosure is not limited thereto. For example, the edge of the first-second open area OA2_1 may have an uneven shape including a plurality of polygonal patterns.

Also, when viewed in a planar perspective, the second-second open area OA2_2 may have an approximately elliptical or rectangular shape, and an edge thereof may have an uneven shape, such as an iris flower pattern, a zigzag pattern, or a wavy pattern, but the present disclosure is not limited thereto. For example, the edge of the second-second open area OA2_2 may have an uneven shape including a plurality of polygonal patterns.

Also, for example, in the first type sub-pixel SP_1, one side portion of the bank 616 facing the first-second open area OA2_1 may have an uneven shape, such as an iris flower pattern, a zigzag pattern, or a wavy pattern, in the same manner as the edge of the first-second open area OA2_1, when viewed in a planar perspective. However, the present disclosure is not limited thereto. The one side portion of the bank 616 may have an uneven shape including a plurality of polygonal patterns.

In addition, for example, in the second type sub-pixel SP_2, another side portion of the bank 616 facing the second-second open area OA2_2 may have an uneven shape, such as an iris flower pattern, a zigzag pattern, or a wavy pattern, in the same manner as the edge of the second-second open area OA2_2, when viewed in a planar perspective. However, the present disclosure is not limited thereto. For example, another side portion of the bank 616 may have an uneven shape including a plurality of polygonal patterns.

In another aspect, the sub-pixels of example embodiments of the present disclosure may have different sizes. Accordingly, the anode electrode, the first open area, and the second open area may have different sizes in different sub-pixels, which will be described in more detail with reference to the drawings.

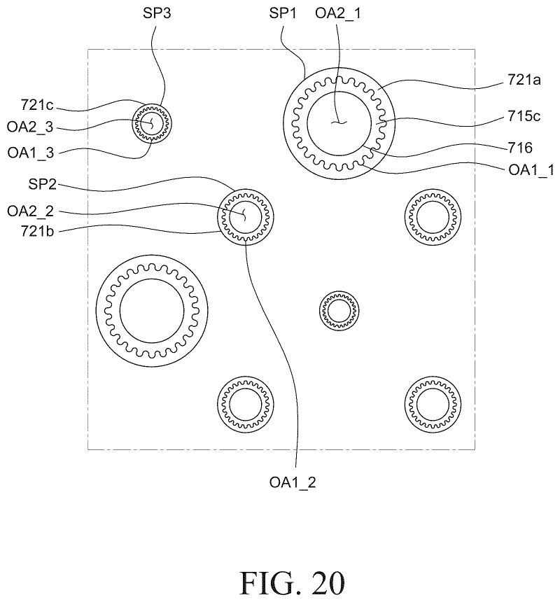

FIG. 20 is a view illustrating a sub-pixel structure of a seventh example embodiment of the present disclosure.

The configurations of the seventh example embodiment of the present disclosure in FIG. 20 may be substantially identical to those of the aforementioned example embodiments with only differences being that sub-pixels SP1, SP2, and SP3 having different sizes are configured. Thus, duplicate descriptions may be omitted.

FIG. 20 illustrates a portion of an example display panel on which eight sub-pixels, including SP1, SP2, and SP3 are disposed. FIG. 20 shows by way of example banks 716 including second open areas OA2_1, OA2_2, and OA2_3 according to the respective sub-pixels SP1, SP2, and SP3, anode electrodes 721a, 721b, and 721c, and a third planarization layer 715c.

As illustrated in FIG. 20, the display panel according to the seventh example embodiment of the present disclosure may include a pixel area in which a plurality of sub-pixels SP1, SP2, and SP3 are present and may include a line area in which various signal lines are disposed.

For example, the plurality of first sub-pixels SP1, second sub-pixels SP2, and third sub-pixels SP3 may be disposed in the pixel area.

The plurality of first sub-pixels SP1, second sub-pixels SP2, and third sub-pixels SP3 may have different sizes but may otherwise have substantially the same configuration except for the sizes.

For example, the first sub-pixel SP1 may be one sub-pixel among red, green, and blue sub-pixels.

For example, the second sub-pixel SP2 may be another sub-pixel among red, green, and blue sub-pixels.

For example, the third sub-pixel SP3 may be the other sub-pixel among red, green, and blue sub-pixels.

Also, the first sub-pixel SP1, the second sub-pixel SP2, and the third sub-pixel SP3 may have an approximately circular shape but are not limited thereto.

Here, the shapes of the sub-pixels SP1, SP2, and SP3 may be defined by shapes of the anode electrodes 721a, 721b, and 721c, but are not limited thereto.

In another aspect, in example embodiments of the present disclosure, the anode electrodes 721a, 721b, and 721c may have a side mirror (SM) structure. Thus, a reflective emission area may be added in addition to a main emission area, so that each emission area can be expanded compared to each of the sub-pixels SP1, SP2 and SP3.

Also, in the seventh example embodiment of the present disclosure, the first sub-pixel SP1 may include a first anode electrode 721a, the second sub-pixel SP2 may include a second anode electrode 721b, and the third sub-pixel SP3 may include a third anode electrode 721c.

For example, the third planarization layer 715c may include first open areas OA1_1, OA1_2, and OA1_3 in which portions corresponding to the main emission areas, the reflective emission areas, and the non-emission areas of the sub-pixels are removed (open). The first open areas OA1_1, OA1_2, and OA1_3 may include a first-first open area OA1_1 of the first sub-pixel SP1, a second-first open area OA1_2 of the second sub-pixel SP2, and a third-first open area OA1_3 of the third sub-pixel SP3. The first-first open area OA1_1, the second-first open area OA1_2, and the third-first open area OA1_3 may have different sizes but may otherwise have the same shape.

Accordingly, when viewed in a planar perspective, the first open areas OA1_1, OA1_2, and OA1_3 may have approximately circular shapes, and edges thereof may have uneven shapes, such as an iris flower pattern, a zigzag pattern, or wavy patterns, but the present disclosure is not limited thereto. For example, the edges of the first open areas OA1_1, OA1_2, and OA1_3 may have uneven shapes including a plurality of polygonal patterns.

In addition, for example, in the first sub-pixel SP1, one side portion of the third planarization layer 715c facing the first-first open area OA1_1 may have an uneven shape, such as an iris flower pattern, a zigzag pattern, or a wavy pattern, in the same manner as the first-first open area OA1_1, when viewed in a planar perspective. However, the present disclosure is not limited thereto. One side portion of the third planarization layer 715c may have an uneven shape including a plurality of polygonal patterns.

Also, for example, in the second sub-pixel SP2, another side portion of the third planarization layer 715c facing the second-first open area OA1_2 may have an uneven shape, such as an iris flower pattern, a zigzag pattern, or a wavy pattern, in the same manner as the edge of the second-first open area OA1_2, when viewed in a planar perspective. However, the present disclosure is not limited thereto. Another side portion of the third planarization layer 715c may have an uneven shape including a plurality of polygonal patterns.

Also, for example, in the third sub-pixel SP3, yet another side portion of the third planarization layer 715c facing the third-first open area OA1_3 may have an uneven shape, such as an iris flower pattern, a zigzag pattern, or a wavy pattern, in the same manner as the edge of the third-first open area OA1_3, when viewed in a planar perspective. However, the present disclosure is not limited thereto. Yet another side portion of the third planarization layer 715c may have an uneven shape including a plurality of polygonal patterns.

According to the seventh example embodiment of the present disclosure, since one side portion of the third planarization layer 715c has an uneven shape, such as an iris flower pattern, a zigzag pattern, or a wavy pattern, a second area of the first anode electrode 721a deposited thereon may also have an uneven shape, such as an iris flower pattern, a zigzag pattern, or a wavy pattern, when viewed in a planar perspective. However, the present disclosure is not limited thereto, and the second area of the first anode electrode 721a according to example embodiments the present disclosure may have an uneven shape including a plurality of polygonal patterns.

According to the seventh example embodiment of the present disclosure, since another side portion of the third planarization layer 715c has an uneven shape, such as an iris flower pattern, a zigzag pattern, or a wavy pattern, a second area of the second anode electrode 721b deposited thereon may also have an uneven shape, such as an iris flower pattern, a zigzag pattern, or a wavy pattern, when viewed on a plane. However, the present disclosure is not limited thereto, and the second area of the second anode electrode 721b according to example embodiments of the present disclosure may have an uneven shape including a plurality of polygonal patterns.

According to the seventh example embodiment of the present disclosure, since yet another side portion of the third planarization layer 715c has an uneven shape, such as an iris flower pattern, a zigzag pattern, or a wavy pattern, a second area of the third anode electrode 721c deposited thereon may also have an uneven shape, such as an iris flower pattern, a zigzag pattern, or a wavy pattern, when viewed on a plane. However, the present disclosure is not limited thereto, and the second area of the third anode electrode 721c according to example embodiments of the present disclosure may have an uneven shape including a plurality of polygonal patterns.

For example, the bank 716 may include second open areas OA2_1, OA2_2, and OA2 3 in which portions corresponding to the main emission areas of the sub-pixels SP1, SP2, and SP3 are removed (open). The first open areas OA1_1, OA1_2, and OA1_3 may have widths greater than those of the second open areas OA2_1, OA2_2, and OA2_3, respectively. The second open areas OA2_1, OA2_2, and OA2_3 may include a first-second open area OA2_1 of the first sub-pixel SP1, a second-second open area OA2_2 of the second sub-pixel SP2, and a third-second open area OA2_3 of the third sub-pixel SP3. The first-second open area OA2_1, the second-second open area OA2_2, and the third-second open area OA2_3 may differ only in size and may otherwise have the same shape.

Accordingly, when viewed in a planar perspective, the second open areas OA2_1, OA2_2, and OA2_3 may have approximately circular shapes, and edges thereof may have uneven shapes, such as an iris flower pattern, a zigzag pattern, or wavy patterns, but the present disclosure is not limited thereto. For example, the edges of the second open areas OA2_1, OA2_2, and OA2_3 may have uneven shapes including a plurality of polygonal patterns.

Also, for example, in the first sub-pixel SP1, one side portion of the bank 716 facing the first-second open area OA2_1 may have an uneven shape, such as an iris flower pattern, a zigzag pattern, or a wavy pattern, in the same manner as the edge of the first-second open area OA2_1, when viewed in a planar perspective, but the present disclosure is not limited thereto. One side portion of the bank 716 may have an uneven shape including a plurality of polygonal patterns.

Also, for example, in the second sub-pixel SP2, another side portion of the bank 716 facing the second-second open area OA2_2 may have an uneven shape, such as an iris flower pattern, a zigzag pattern, or a wavy pattern, in the same manner as the edge of the second-second open area OA2_2, when viewed in a planar perspective, but the present disclosure is not limited thereto. For example, another side portion of the bank 716 may have an uneven shape including a plurality of polygonal patterns.

Further, for example, in the third sub-pixel SP3, yet another side portion of the bank 716 facing the third-second open area OA2_3 may have an uneven shape, such as an iris flower pattern, a zigzag pattern, or a wavy pattern, in the same manner as the edge of the third-second open area OA2_3, when viewed in a planar perspective, but the present disclosure is not limited thereto. For example, yet another side of the bank 716 may have an uneven shape including a plurality of polygonal patterns.

Various example embodiments of the present disclosure can also be described as follows:

According to an example embodiment, a display device may include: a substrate including a plurality of sub-pixels, including a first sub-pixel; an insulating layer disposed over the substrate and having a first open area in the first sub-pixel, the insulating layer having a side portion facing the first open area in the first sub-pixel; an anode electrode including a first portion disposed in the first open area and a second portion disposed on the side portion of the insulating layer; an organic layer on the anode electrode; and a cathode electrode on the organic layer, wherein the first open area of the insulating layer may have an uneven outer edge in a plan view.

In some example embodiments, the uneven outer edge of the first open area of the insulating layer may include an iris flower pattern, a wavy pattern, a zigzag pattern, or a plurality of polygonal patterns in the plan view.

In some example embodiments, the anode electrode may further include a third portion extending from the second portion and disposed on an upper surface of the insulating layer, and the side portion of the insulating layer may be inclined with respect to the upper surface of the insulating layer.

In some example embodiments, the display device may further include a transistor disposed over the substrate and under the insulating layer in the first sub-pixel. The insulating layer may further include a contact hole spaced apart from the first open area, and the anode electrode may be connected to the transistor through the contact hole.

In some example embodiments: the anode electrode, the organic layer, and the cathode electrode may constitute a light emitting element of the first sub-pixel; the light emitting element may form a main emission area of the first sub-pixel; the second portion of the anode electrode may form a reflective emission area of the first sub-pixel around the main emission area of the first sub-pixel; and a non-emission area may be formed between the main emission area and the reflective emission area.

In some example embodiments, the second portion of the anode electrode may have an uneven shape corresponding to the uneven outer edge of the first open area of the insulating layer, and an outer edge of the reflective emission area may have a shape corresponding to the uneven shape of the second portion of the anode electrode.

In some example embodiments, in the plan view: the main emission area may have a circular, polygonal, or elliptical shape; an inner edge of the reflective emission area may have a shape corresponding to the shape of the main emission area; an outer edge of the reflective emission area may have an uneven shape different from the shape of the main emission area and including an iris flower pattern, a wavy pattern, a zigzag pattern, or a plurality of polygonal patterns; and the non-emission area may have a shape of a circular, polygonal, or elliptical ring surrounding the main emission area and corresponding to the shape of the main emission area.

In some example embodiments, in the plan view: an outer edge of the reflective emission area may have an uneven shape including an iris flower pattern, a wavy pattern, a zigzag pattern, or a plurality of polygonal patterns; and an outer edge of the main emission area may have an uneven shape corresponding to the uneven shape of the outer edge of the reflective emission area.

In some example embodiments, the display device may further include a bank over the anode electrode and having a second open area exposing an area of the first portion of the anode electrode in the first open area of the insulating layer.

In some example embodiments, the first open area may have a greater width than the second open area and may encompass the second open area in the plan view, and the bank may cover the second portion of the anode electrode.

In some example embodiments, an outer edge of the second open area may have a different shape from the uneven outer edge of the first open area in the plan view.

In some example embodiments, in the plan view: the uneven outer edge of the first open area may include an iris flower pattern, a wavy pattern, a zigzag pattern, or a plurality of polygonal patterns; and the outer edge of the second open area may have a circular, polygonal, or elliptical shape.

In some example embodiments, in the plan view: the uneven outer edge of the first open area may include an iris flower pattern, a wavy pattern, a zigzag pattern, or a plurality of polygonal patterns; and an outer edge of the second open area may have an uneven shape corresponding to the uneven outer edge of the first open area.

In some example embodiments, the bank may have a side portion facing the second open area, and the side portion of the bank may have a different shape from the side portion of the insulating layer, the side portion of the insulating layer having an uneven shape corresponding to the uneven outer edge of the first open area in the plan view.

In some example embodiments: the bank may have a side portion facing the second open area; the side portion of the insulating layer may have an uneven shape corresponding to the uneven outer edge of the first open area in the plan view; and the side portion of the bank may have an uneven shape corresponding to the uneven shape of the side portion of the insulating layer.

In some example embodiments: the plurality of sub-pixels may further include a second sub-pixel; the insulating layer may further have another first open area in the second sub-pixel and another side portion facing the other first open area in the second sub-pixel; and the other first open area of the insulating layer in the second sub-pixel may have a differently shaped outer edge from the uneven outer edge of the first open area of the insulating layer in the first sub-pixel in the plan view.

In some example embodiments: the plurality of sub-pixels may further include a second sub-pixel; the insulating layer may further have another first open area in the second sub-pixel and another side portion facing the other first open area in the second sub-pixel; and the other first open area of the insulating layer in the second sub-pixel may have an uneven outer edge having a shape corresponding to a shape of the uneven outer edge of the first open area of the insulating layer in the first sub-pixel in the plan view.

In some example embodiments, the second sub-pixel may have a different size from the first sub-pixel, and the other first open area in the second sub-pixel has a different size from the first open area in the first sub-pixel.

According to an example embodiment, a display device may include: a substrate including plurality of sub-pixels configured to emit light, the plurality of sub-pixels including a first sub-pixel; an insulating layer over the substrate; an anode electrode on the insulating layer; an organic layer on the anode electrode; and a cathode electrode on the organic layer. The anode electrode, the organic layer, and the cathode electrode in the first sub-pixel in combination may be configured to emit light, and the first sub-pixel may include an emission area with an uneven outer edge in a plan view.

In some example embodiments, the uneven outer edge of the emission area of the first sub-pixel may include an iris flower pattern, a wavy pattern, a zigzag pattern, or a plurality of polygonal patterns in the plan view.

In some example embodiments, the emission area of the first sub-pixel may include a main emission area and a reflective emission area around the main emission area.

In some example embodiments, a non-emission area may be formed between the main emission area and the reflective emission area, the non-emission area having a shape corresponding to the shape of the main emission area.

In some example embodiments, in the plan view: the main emission area may have a circular, polygonal, or elliptical shape; an inner edge of the reflective emission area may have a shape corresponding to the shape of the main emission area; and an outer edge of the reflective emission area may have an uneven shape different from the shape of the main emission area and including an iris flower pattern, a wavy pattern, a zigzag pattern, or a plurality of polygonal patterns.

In some example embodiments, in the plan view: an outer edge of the reflective emission area may have an uneven shape including an iris flower pattern, a wavy pattern, a zigzag pattern, or a plurality of polygonal patterns; and an outer edge of the main emission area may have an uneven shape corresponding to the uneven shape of the outer edge of the reflective emission area.

In some example embodiments, the plurality of sub-pixels may further include a second sub-pixel, and the second sub-pixel may include an emission area having a differently shaped outer edge from the uneven outer edge of the emission area in the first sub-pixel in the plan view.

In some example embodiments: the plurality of sub-pixels may further include a second sub-pixel having an emission area; the emission area of the second sub-pixel may include an uneven outer edge having a shape corresponding to a shape of the uneven outer edge of the emission area in the first sub-pixel in the plan view; and the emission area of the second sub-pixel may have a different size from the emission area of the first sub-pixel.

It will be apparent to those skilled in the art that the present disclosure is not limited by the above-described example embodiments and the accompanying drawings and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. A display device, comprising:
a substrate including a plurality of sub-pixels, including a first sub-pixel;
an insulating layer disposed over the substrate and having a first open area in the first sub-pixel, the insulating layer having a side portion facing the first open area in the first sub-pixel;
an anode electrode including a first portion disposed in the first open area and a second portion disposed on the side portion of the insulating layer;
an organic layer on the anode electrode; and
a cathode electrode on the organic layer,
wherein the first open area of the insulating layer has an uneven outer edge in a plan view.

2. The display device of claim 1, wherein the uneven outer edge of the first open area of the insulating layer includes an iris flower pattern, a wavy pattern, a zigzag pattern, or a plurality of polygonal patterns in the plan view.

3. The display device of claim 1, wherein:
the anode electrode further includes a third portion extending from the second portion and disposed on an upper surface of the insulating layer; and
the side portion of the insulating layer is inclined with respect to the upper surface of the insulating layer.

4. The display device of claim 3, further comprising:
a transistor disposed over the substrate and under the insulating layer in the first sub-pixel,
wherein:
the insulating layer further includes a contact hole spaced apart from the first open area; and
the anode electrode is connected to the transistor through the contact hole.

5. The display device of claim 1, wherein:
the anode electrode, the organic layer, and the cathode electrode constitute a light emitting element of the first sub-pixel;
the light emitting element forms a main emission area of the first sub-pixel;
the second portion of the anode electrode forms a reflective emission area of the first sub-pixel around the main emission area of the first sub-pixel; and
a non-emission area is formed between the main emission area and the reflective emission area.

6. The display device of claim 5, wherein:
the second portion of the anode electrode has an uneven shape corresponding to the uneven outer edge of the first open area of the insulating layer; and
an outer edge of the reflective emission area has a shape corresponding to the uneven shape of the second portion of the anode electrode.

7. The display device of claim 5, wherein in the plan view:
the main emission area has a circular, polygonal, or elliptical shape;
an inner edge of the reflective emission area has a shape corresponding to the shape of the main emission area;
an outer edge of the reflective emission area has an uneven shape different from the shape of the main emission area and including an iris flower pattern, a wavy pattern, a zigzag pattern, or a plurality of polygonal patterns; and
the non-emission area has a shape of a circular, polygonal, or elliptical ring surrounding the main emission area and corresponding to the shape of the main emission area.

8. The display device of claim 5, wherein in the plan view:
an outer edge of the reflective emission area has an uneven shape including an iris flower pattern, a wavy pattern, a zigzag pattern, or a plurality of polygonal patterns; and
an outer edge of the main emission area has an uneven shape corresponding to the uneven shape of the outer edge of the reflective emission area.

9. The display device of claim 1, further comprising:
a bank over the anode electrode and having a second open area exposing an area of the first portion of the anode electrode in the first open area of the insulating layer.

10. The display device of claim 9, wherein:
the first open area has a greater width than the second open area and encompasses the second open area in the plan view; and
the bank covers the second portion of the anode electrode.

11. The display device of claim 9, wherein an outer edge of the second open area has a different shape from the uneven outer edge of the first open area in the plan view.

12. The display device of claim 11, wherein in the plan view:
the uneven outer edge of the first open area includes an iris flower pattern, a wavy pattern, a zigzag pattern, or a plurality of polygonal patterns; and
the outer edge of the second open area has a circular, polygonal, or elliptical shape.

13. The display device of claim 9, wherein in the plan view:
the uneven outer edge of the first open area includes an iris flower pattern, a wavy pattern, a zigzag pattern, or a plurality of polygonal patterns; and
an outer edge of the second open area has an uneven shape corresponding to the uneven outer edge of the first open area.

14. The display device of claim 9, wherein:
the bank has a side portion facing the second open area; and
the side portion of the bank has a different shape from the side portion of the insulating layer, the side portion of the insulating layer having an uneven shape corresponding to the uneven outer edge of the first open area in the plan view.

15. The display device of claim 9, wherein:
the bank has a side portion facing the second open area;
the side portion of the insulating layer has an uneven shape corresponding to the uneven outer edge of the first open area in the plan view; and
the side portion of the bank has an uneven shape corresponding to the uneven shape of the side portion of the insulating layer.

16. The display device of claim 1, wherein:
the plurality of sub-pixels further includes a second sub-pixel;
the insulating layer further has another first open area in the second sub-pixel and another side portion facing the other first open area in the second sub-pixel; and
the other first open area of the insulating layer in the second sub-pixel has a differently shaped outer edge from the uneven outer edge of the first open area of the insulating layer in the first sub-pixel in the plan view.

17. The display device of claim 1, wherein:
the plurality of sub-pixels further includes a second sub-pixel;
the insulating layer further has another first open area in the second sub-pixel and another side portion facing the other first open area in the second sub-pixel; and
the other first open area of the insulating layer in the second sub-pixel has an uneven outer edge having a shape corresponding to a shape of the uneven outer edge of the first open area of the insulating layer in the first sub-pixel in the plan view.

18. The display device of claim 17, wherein in the plan view:
the second sub-pixel has a different size from the first sub-pixel; and
the other first open area in the second sub-pixel has a different size from the first open area in the first sub-pixel.

19. A display device, comprising:
a substrate including a plurality of sub-pixels configured to emit light, the plurality of sub-pixels including a first sub-pixel;
an insulating layer over the substrate;
an anode electrode on the insulating layer;
an organic layer on the anode electrode; and
a cathode electrode on the organic layer,
wherein the anode electrode, the organic layer, and the cathode electrode in the first sub-pixel in combination are configured to emit light, and
wherein the first sub-pixel includes an emission area with an uneven outer edge in a plan view.

20. The display device of claim 19, wherein the uneven outer edge of the emission area of the first sub-pixel includes an iris flower pattern, a wavy pattern, a zigzag pattern, or a plurality of polygonal patterns in the plan view.

21. The display device of claim 19, wherein the emission area of the first sub-pixel includes:
a main emission area; and
a reflective emission area around the main emission area.

22. The display device of claim 21, wherein a non-emission area is formed between the main emission area and the reflective emission area, the non-emission area having a shape corresponding to the shape of the main emission area.

23. The display device of claim 21, wherein in the plan view:
the main emission area has a circular, polygonal, or elliptical shape;
an inner edge of the reflective emission area has a shape corresponding to the shape of the main emission area; and
an outer edge of the reflective emission area has an uneven shape different from the shape of the main emission area and including an iris flower pattern, a wavy pattern, a zigzag pattern, or a plurality of polygonal patterns.

24. The display device of claim 21, wherein in the plan view:
an outer edge of the reflective emission area has an uneven shape including an iris flower pattern, a wavy pattern, a zigzag pattern, or a plurality of polygonal patterns; and
an outer edge of the main emission area has an uneven shape corresponding to the uneven shape of the outer edge of the reflective emission area.

25. The display device of claim 19, wherein:
the plurality of sub-pixels further includes a second sub-pixel; and
the second sub-pixel includes an emission area having a differently shaped outer edge from the uneven outer edge of the emission area in the first sub-pixel in the plan view.

26. The display device of claim 19, wherein:
the plurality of sub-pixels further includes a second sub-pixel having an emission area;
the emission area of the second sub-pixel includes an uneven outer edge having a shape corresponding to a shape of the uneven outer edge of the emission area in the first sub-pixel in the plan view, and
the emission area of the second sub-pixel has a different size from the emission area of the first sub-pixel.
